(19) United States
(12) Patent Application Publication
(10) Pub. No.: US 2025/0294951 A1
(43) Pub. Date: Sep. 18, 2025

(54) PHOTOELECTRIC CONVERSION ELEMENT, SOLAR CELL MODULE, AND SOLAR WATER HEATER

(71) Applicant: Yuuji TANAKA, Shizuoka (JP)

(72) Inventor: Yuuji TANAKA, Shizuoka (JP)

(21) Appl. No.: 19/075,815

(22) Filed: Mar. 11, 2025

(30) Foreign Application Priority Data
Mar. 12, 2024 (JP) 2024-037701

(51) Int. Cl. H10K 30/50; F24S 60/30; H10K 30/81; H10K 30/85; H10K 30/86; H10K 30/88; H10K 39/12; H10K 85/10; H10K 85/60

(52) U.S. Cl. CPC H10K 30/50; F24S 60/30; H10K 30/81; H10K 30/85; H10K 30/86; H10K 30/88; H10K 39/12; H10K 85/111; H10K 85/615; H10K 85/633; H10K 85/654; H10K 85/658

(57) ABSTRACT

A photoelectric conversion element is provided that includes: a first electrode including a metal nanowire; a hole transport layer over the first electrode, including a polymer of a hole transport material; a photoelectric conversion layer over the hole transport layer; an electron transport layer over the photoelectric conversion layer; and a second electrode over the electron transport layer.

### CROSS-REFERENCE TO RELATED APPLICATIONS

This patent application is based on and claims priority pursuant to 35 U.S.C. § 119(a) to Japanese Patent Application No. 2024-037701, filed on Mar. 12, 2024, in the Japan Patent Office, the entire disclosure of which is hereby incorporated by reference herein.

### BACKGROUND

### Technical Field

The present disclosure relates to a photoelectric conversion element, a solar cell module, and a solar water heater.

### Related Art

In recent years, solar cells utilizing photoelectric conversion elements represent a technique with expectations in a wide range of applications, not only as an alternative to fossil fuels and a measure against global warming, but also as independent power sources that do not require battery replacement, power wiring, or the like. Further, solar cells as independent power sources are also attracting attention as one of the energy harvesting technologies required for Internet of Things (IoT) devices and artificial satellites.

Types of solar cells include inorganic solar cells using silicon or the like, which have been widely used until now, and organic solar cells such as dye-sensitized solar cells, organic thin-film solar cells, and perovskite solar cells. Perovskite solar cells can be manufactured by using known printing means, without using electrolytes containing organic solvents and the like, and thus, are advantageous to improve the safety and reduce the manufacturing costs.

It is also known that, when manufacturing large-area perovskite solar cells based on inkjet printing, silver nanowires are used to manufacture electrodes.

### SUMMARY

Embodiments of the present invention provides a photoelectric conversion element that includes: a first electrode including a metal nanowire; a hole transport layer over the first electrode, including a polymer of a hole transport material; a photoelectric conversion layer over the hole transport layer; an electron transport layer over the photoelectric conversion layer; and a second electrode over the electron transport layer.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic diagram illustrating an inverted structure-type solar cell as a photoelectric conversion element according to an embodiment of the present invention;

FIG. 2 is a schematic diagram illustrating an inverted structure-type solar cell as a photoelectric conversion element according to an embodiment of the present invention;

FIG. 3 is a schematic diagram illustrating a solar cell module according to an embodiment of the present invention;

FIG. 4 is a schematic diagram illustrating a solar cell module according to an embodiment of the present invention;

FIG. 5 is a schematic diagram illustrating a solar cell module according to an embodiment of the present invention;

FIG. 6 is a graph illustrating an IR spectrum of Compound No. 1 in Synthesis Example 1; and

FIG. 7 is a graph illustrating an infrared light transmittance of a first electrode and a first substrate in Example 1.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a”, “an”, and “the” are intended to include the plural forms as well, unless the context clearly indicates otherwise.

According to embodiments of the present invention, a photoelectric conversion element is provided that has light resistance, heat resistance, infrared light transmittance, and excellent conversion efficiency.

### (Photoelectric Conversion Element)

The photoelectric conversion element refers to an element that can convert light energy into electric energy or convert electric energy into light energy, and is applied to solar cells, photodiodes, and the like.

The photoelectric conversion element according to an embodiment of the present invention is a so-called inverted structure-type photoelectric conversion element including a first substrate, a first electrode, a hole transport layer, a photoelectric conversion layer, an electron transport layer, and a second electrode, in this order.

The first electrode contains a metal nanowire and the hole transport layer contains a polymer of a hole transport material.

The inverted structure-type photoelectric conversion element preferably further includes a passivation layer between the photoelectric conversion layer and the electron transport layer.

The inventors discovered issues in the related art and made the following findings, which led to a photoelectric conversion element according to an embodiment of the present invention.

That is, electrodes containing metal nanowires have higher infrared light transmittance than ITO substrates, so that infrared light can be effectively utilized. However, silver nanowires pose the problem of silver corrosion by halogen ions derived from the perovskite layer. Adsorption-type hole transport materials (such as hole transport materials having phosphonic acid groups or carboxylic acid groups) by which high output can be obtained in inverted structure-type perovskite solar cells, do not chemically adhere to metal nanowire materials. Thus, it is not possible to obtain high conversion efficiency and durability in photoelectric conversion elements.

Further, a known hole transport layer includes a conductive polymer such as poly(3,4-ethylenedioxythiophene) doped with poly(4-styrenesulfonic acid) (PEDOT/PSS). The document “Bowen Gao and Jing Meng, Solar Energy, vol. 230, p. 598-604 (2021)” reports a perovskite solar cell that combinedly uses an electrode containing silver nanowires and a hole transport layer containing PEDOT/PSS. However, in this technology, the photoelectric conversion element has poor light resistance.

As a result of intensive research conducted by the inventors to solve the above-mentioned problems and achieve the above-mentioned object, the inventors have found that it is possible to provide a photoelectric conversion element that is light resistant, heat resistant, transmits infrared light, and has excellent conversion efficiency, and thus, have completed the present invention. The photoelectric conversion element includes a first substrate, a first electrode, a hole transport layer, a photoelectric conversion layer, an electron transport layer, and a second electrode, in this order. The first electrode includes a metal nanowire. The hole transport layer includes a polymer of a hole transport material. That is, firstly, the hole transport layer includes a polymer of a hole transport material, and thus, it is possible to achieve high conversion efficiency and improved light resistance by the excellent charge injection properties in the first electrode and the photoelectric conversion layer, each of which contains a metal nanowire. Secondly, it is possible to prevent halogen corrosion from the photoelectric conversion layer of the silver nanowire material, and thus, achieve improved heat resistance. Thirdly, the first electrode includes a metal nanowire, and thus, the photoelectric conversion element has excellent infrared light transmittance.

In addition, in a tandem-type solar cell module, a top cell (a photoelectric conversion element on a side of a light-receiving surface) may be used in which a first electrode containing a metal nanowire and a second electrode (a translucent counter electrode) containing a metal nanowire are combined. Such a top cell has excellent infrared light transmittance, and thus, high conversion efficiency can be achieved in the solar cell module.

Further, in a solar water heater including the photoelectric conversion element according to an embodiment of the present invention, since the infrared light transmittance of the photoelectric conversion element is high, the transmitted infrared light can be collected and efficiently utilized to heat hot water. In addition, the heat generated by the photoelectric conversion element can be utilized to heat hot water, which contributes to higher efficiency of the solar water heater including the photoelectric conversion element.

### First Substrate

The shape, the structure, and the size of the first substrate are not particularly limited and can be appropriately selected according to a purpose.

The material of the first substrate is not particularly limited and can be appropriately selected according to a purpose, as long as the material transmits infrared light and has insulating properties. Examples of the material include, but are not limited to, substrates made of glass, plastic films, and ceramics. Among these substrates, when a firing step is included in the formation of the electron transport layer as described below, it is preferable to use a substrate having heat resistance to the firing temperature. Further, it is more preferable that a flexible substrate is used as the first substrate.

A second substrate may be provided on an outermost portion on the side of the second electrode. The shape, the structure, the size, and the materials described for the first substrate can be appropriately selected for the second substrate.

Hereinafter, a substrate provided at an outermost portion on the side of the first electrode will be referred to as a first substrate, and a substrate provided at the outermost portion on the side of the second electrode will be referred to as a second substrate. The first substrate and the second substrate will be collectively referred to as a substrate.

The average thickness of the substrate is not particularly limited and can be appropriately selected according to a purpose. For example, the average thickness may be 50 m or more and 5 mm or less.

### First Electrode

The shape and the size of the first electrode are not particularly limited and can be appropriately selected according to a purpose, as long as the first electrode contains a metal nanowire and transmits infrared light.

Hereinafter, an electrode provided on a side of the first substrate will be referred to as a first electrode, and an electrode provided on a side of the second substrate will be referred to as a second electrode. The first electrode and the second electrode will be collectively referred to as an electrode.

The structure of the first electrode is not particularly limited and can be appropriately selected according to a purpose. The structure may be a single-layer structure or a structure in which a plurality of materials are laminated.

### —Metal Nanowire—

The metal nanowire is not particularly limited and can be appropriately selected according to a purpose. Preferable examples include, but are not limited to, nanowires made of a metal selected from the group consisting of silver, a silver alloy, copper, and a copper alloy, and more preferable examples include, but are not limited to, silver nanowires and nanowires made of a silver alloy.

In the first electrode, a plurality of metal nanowires are partially contacting each other or are fused to each other to form a network structure such as a mesh or a lattice. Thus, a plurality of conductive paths are formed, and an interconnected conductive cluster or conductive layer is formed. To increase the conductivity of the first electrode, it is preferable that the density of the metal nanowire is high. On the other hand, to obtain an electrode to be used in an element having transparency and flexibility, it is preferable that the density of the nanowires is equal to or lower than a certain level.

The content and the coating amount of the metal nanowires in the first electrode are not particularly limited and can be appropriately selected according to a purpose. However, to achieve sufficient transparency, flexibility, and conductivity of the obtained first electrode, the content and the coating amount are preferably 0.05 g/m² to 50 g/m², more preferably 0.1 g/m² to 10 g/m², and even more preferably 0.15 g/m² to 1 g/m².

The size of the metal nanowire is not particularly limited and can be appropriately selected according to a purpose. Generally, a conductive cluster is more easily formed by longer nanowires, and nanowires having a larger diameter are more conductive.

The diameter of the metal nanowire is preferably 10 nm to 500 nm, more preferably 20 nm to 150 nm, and even more preferably 30 nm to 120 nm, to achieve sufficient transparency, flexibility, and conductivity in the obtained first electrode.

If the diameter is less than 10 nm, the electric resistance of the nanowire tends to be large. If the diameter exceeds 500 nm, light scattering and the like may increase, so that the transparency decreases. On the other hand, the diameter is preferably from 10 nm to 500 nm.

The length of the metal nanowire is preferably 0.1 μm to 50 μm, more preferably 1 μm to 40 μm, and even more preferably 5 μm to 30 μm, to achieve sufficient transparency, flexibility, and conductivity in the obtained first electrode.

If the length of the metal nanowire is less than 0.1 μm, the conductive cluster is not sufficiently formed, and the electric resistance tends to increase. If the length exceeds 50 μm, a dispersion process in a solvent while manufacturing an electrode or the like tends to be unstable.

The diameter and the length of the metal nanowire can be measured, for example, by analyzing a SEM image captured with a scanning electron microscope (SEM).

A method of manufacturing the metal nanowire is not particularly limited and can be appropriately selected according to a purpose. For example, to manufacture silver nanowires, an aqueous solution of silver ions may be reduced by using various reducing agents. The shape and the size of the silver nanowires can be controlled by selecting the type of the reducing agent being used, a protective polymer or dispersant, and coexisting ions.

When manufacturing silver nanowires, it is preferable to use a polyhydric alcohol such as ethylene glycol as the reducing agent and polyvinylpyrrolidone or a derivative thereof as the protective polymer.

By using such raw materials, it is possible to obtain so-called nanowires on the nanometer order.

The first electrode may contain only the metal nanowire, but may also contain other components such as a binder polymer; and conductive materials such as a conductive polymer, metal nanoparticles, and conductive oxide nanoparticles.

Depending on the type of the binder polymer, the binder polymer may function as a binder for the metal nanowire or improve the adhesion between the first electrode and the first substrate, so that peeling of the first electrode can be prevented.

Examples of the binder polymer include, but are not limited to, polyolefins, acrylic polymers, and polyurethane-based polymers, which have a polar group.

When the metal nanowire is used in combination with the binder polymer, the content of the binder polymer is preferably low to maintain the electric resistance of the first electrode, and is preferably 5 parts by mass or lower with respect to 100 parts by mass of the total amount of the first electrode.

In one embodiment, the first electrode preferably further contains a conductive polymer, and a mass ratio (A/B) of the metal nanowire (A) to the conductive polymer (B) in the first electrode is 2 or more and 6 or less.

The average thickness of the first electrode is not particularly limited and may be appropriately selected according to a purpose, but is preferably 5 nm or more and 100 μm or less, and more preferably 50 nm or more and 10 μm or less. When the material of the first electrode includes carbon or a metal, the average thickness of the first electrode is preferably set to an average thickness at which it is possible to obtain light transmittance.

The first electrode can be formed by a known method such as a die coating method, a spin coating method, a spray method, and an inkjet method.

Examples of materials in a metal lead wire include, but are not limited to, aluminum, copper, silver, gold, platinum, and nickel.

For example, the metal lead wire can be formed on the substrate by a vapor deposition method, a sputtering method, a pressure bonding method, or the like, and then, a layer of the metal nanowire can be provided on the metal lead wire. Alternatively, the metal lead wire can be provided on the first electrode and used in combination with the first electrode.

### <Hole Transport Layer>

The hole transport layer refers to a layer that transports holes (positive holes) generated in the photoelectric conversion layer to the first electrode adjacent to the hole transport layer. Therefore, the hole transport layer is preferably arranged adjacent to the photoelectric conversion layer, directly or via a salt.

The hole transport layer contains a polymer of a hole transport material, and further contains other components, if desired.

### <<Hole Transport Material>>

The hole transport material is a material that includes a polymerizable group and can form a polymer, and the polymer has a hole transporting property.

The polymerizable group is not particularly limited, as long as the polymerizable group is a group that can be polymerized. For example, a known polymerizable group can be appropriately selected according to a purpose. Examples of the polymerizable group include, but are not limited to, a group having a carbon-carbon multiple bond, a group having a small ring, and a combination of groups that can form an ester bond and an amide bond.

These polymerizable groups may be used alone or in combination of two or more types. Further, the polymerizable group may include a substituent as a coupling group (divalent group).

Examples of the group having a carbon-carbon multiple bond include, but are not limited to, a vinyl group, an acetylene group (ethynyl group), a butenyl group, an acryl group (acryloyl group), an acrylate group (acryloyloxy group), an acrylamide group (acryloylamino group), a methacryl group (methacryloyl group), a methacrylate group (methacryloyloxy group), a methacrylamide group (methacryloylamino group), an aryl group, an allyl group, a vinyl ether group (vinyloxy group), a vinylamino group, a furanyl group, a pyrrolyl group, a thiophenyl group, and a silolyl group.

Examples of the group having a small ring include, but are not limited to, a cyclopropyl group, a cyclobutyl group, an epoxy group (oxiranyl group), an oxetane group (oxetanyl group), a diketene group, an episulfide group; a lactone group, and a lactam group.

Examples of the combination of groups that can form an ester bond and an amide bond include, but are not limited to, a combination of an ester group and an amino group, and a combination of an ester group and a hydroxyl group.

Among the polymerizable groups mentioned above, the oxetane group, the epoxy group, the vinyl group, the vinyl ether group, the acrylate group, and the methacrylate group are preferred from the viewpoint of reactivity.

The hole transport material may include a pyridine group or may not include a pyridine group. However, to obtain higher light resistance, it is preferable that the hole transport material includes a pyridine group, and it is more preferable that the hole transport material is a compound represented by General Formula (1) below.

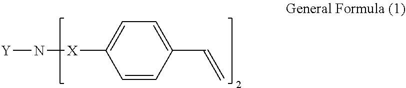

In General Formula (1) above, X represents an aromatic hydrocarbon group that may include a substituent, and Y represents a pyridine group that may include a substituent.

The aromatic hydrocarbon group of X is preferably a benzene ring.

The substituent for X may be a monovalent group or may be a divalent group.

Examples of the substituent include, but are not limited to, alkyl groups such as a methyl group and an ethyl group; alkylene groups such as a methylene group and an ethylene group; and alkene groups such as an ethenyl group (—CH═CH—).

In General Formula (1) above, X is preferably selected from the groups below.

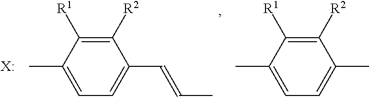

Here, R¹ and R² each independently represent a hydrogen atom or a methyl group.

The compounds and the substituents may include any cis-trans isomers.

In particular, in the above-described X having an ethenyl group as a substituent, the ethenyl group may be a cis isomer, a trans isomer, or may be in a mixed state of a cis isomer and a trans isomer. However, from the viewpoint of solubility, it is preferable that X contains a cis isomer, and it is preferable that the ethenyl group is in a mixed state of a cis isomer and a trans isomer (a cis-trans mixed ethenyl group).

Suitable examples of the substituent for Y include, but are not limited to, divalent groups such as alkylene groups including a methylene group and an ethylene group; and arylene groups including a phenylene group and a naphthylene group. The arylene group may include a substituent, and examples of the substituent include, but are not limited to, an alkyl group such as a methyl group and an ethyl group.

In consideration of the energy level and the charge transporting properties, the substituent for Y is preferably an arylene group, and the pyridine group in Y preferably does not have a monovalent group.

In General Formula (1) above, Y is preferably selected from the groups below.

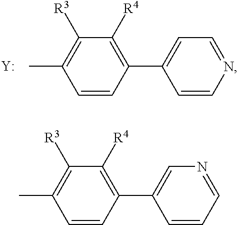

Here, R³ and R⁴ each independently represent a hydrogen atom or a methyl group.

Examples of the hole transport material represented by General Formula (1) above include, but are not limited to, Compounds No. 1 to No. 13 below.

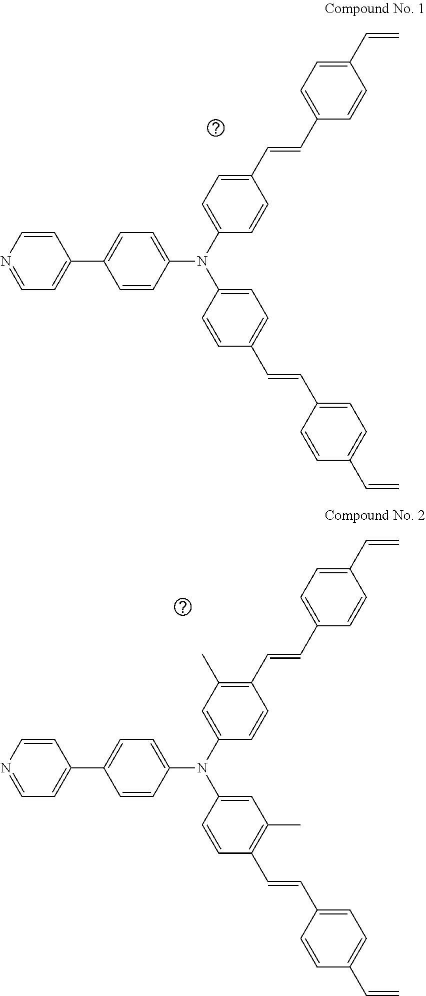

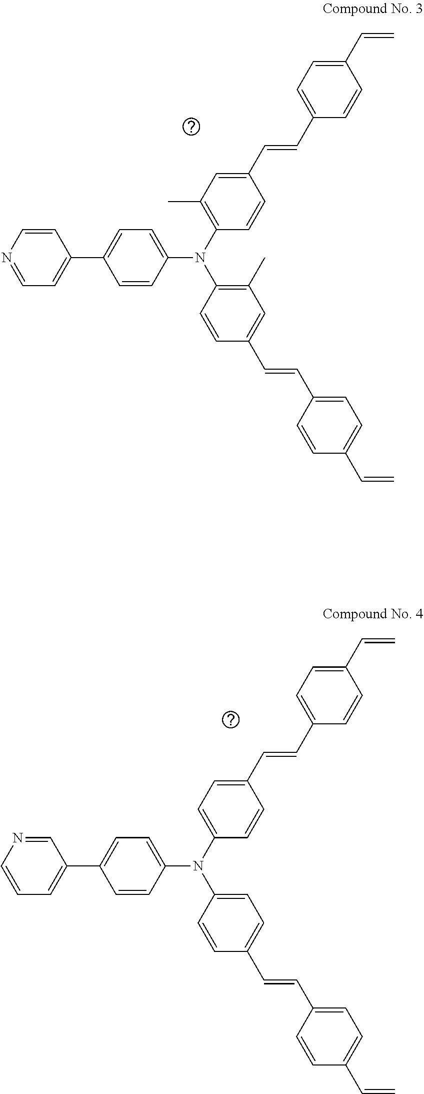

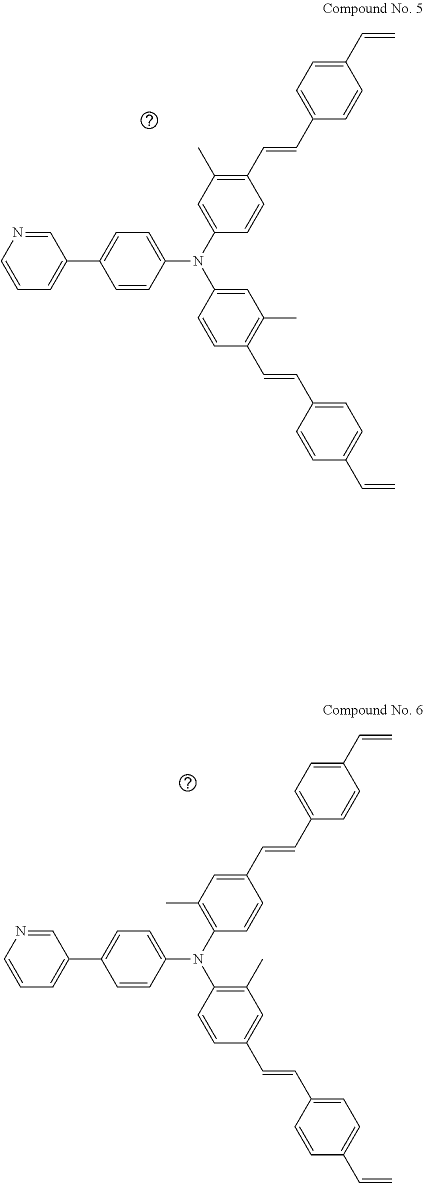

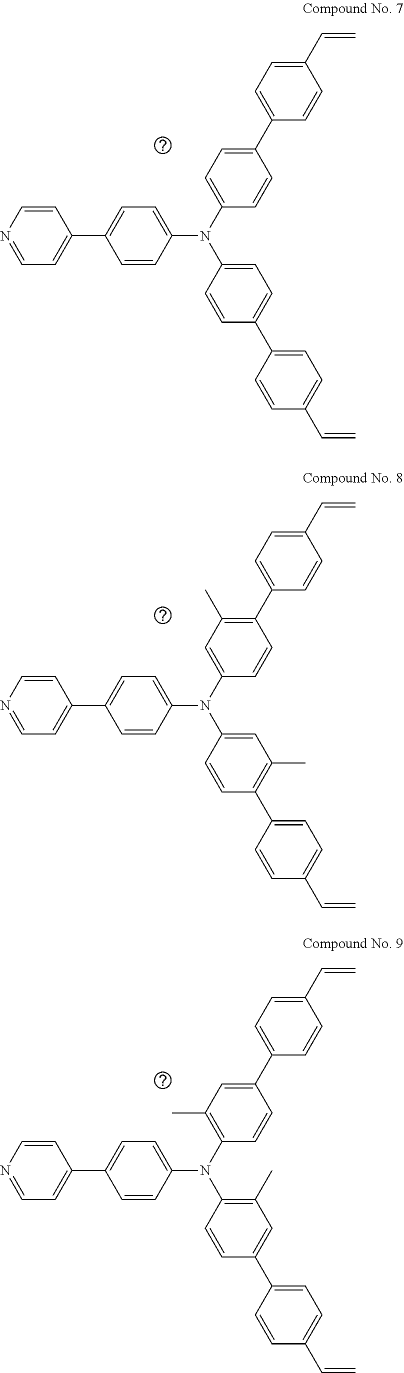

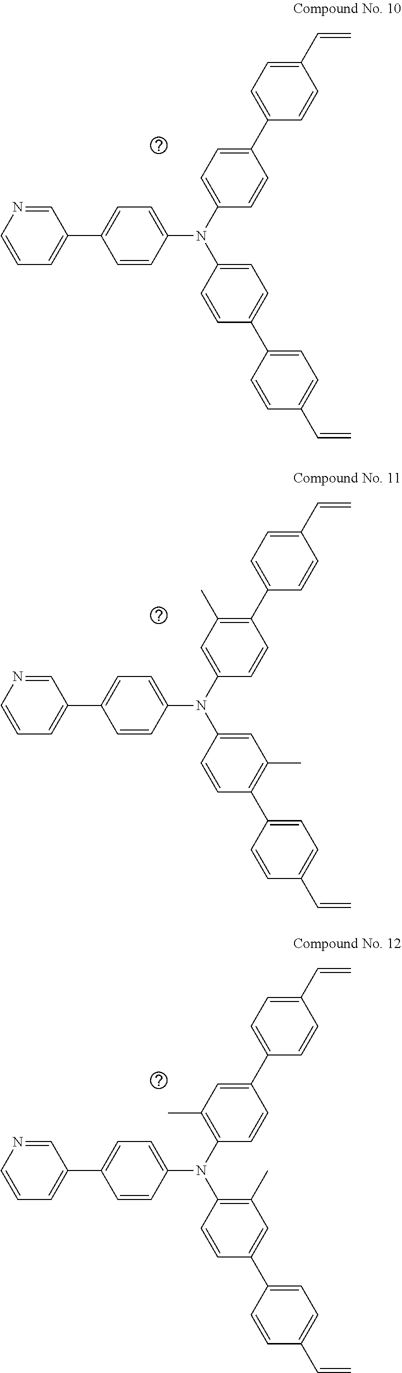

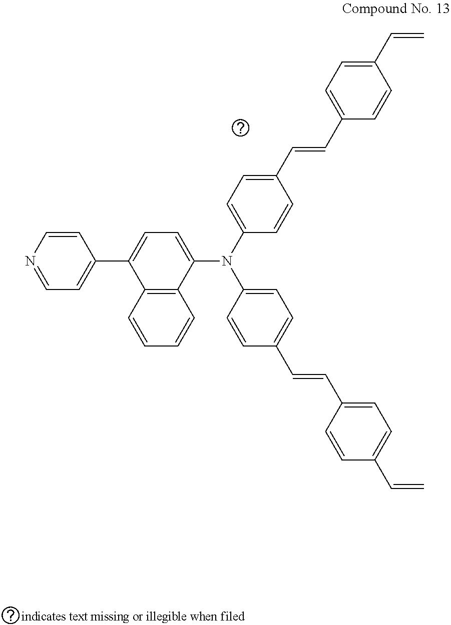

In organic electronic devices (e.g., organic photoconductors, organic LEDs) such as organic solar cells, a hole transport material is laminated and coated on a functional layer formed as a film. The hole transport material is preferably insoluble in the coating solvent. Various methods of obtaining an insoluble hole transport material are known (such as thermal curing, ultraviolet curing, and electron beam curing).

The hole transport material represented by General Formula (1) has the following properties (1) to (3). Therefore, it is possible to provide a hole transport material that has solvent resistance and can be used to manufacture a photoelectric conversion element having high durability. The hole transport material can be suitably used as a hole transport material for thermal cross-linking and as a hole transport layer (HTL) in an inverted structure-type perovskite solar cell (PSC).

(1) A polymerizable group that can form a (three-dimensional) polymerized molecular structure by a thermal reaction, (2) a polymerizable group having high thermal reactivity, located at the N-para position of a triphenylamine structure, and (3) a pyridine group, which is known to chemically coordinate to a perovskite crystal structure.

In a case where X in General Formula (1) above includes a mixed cis-trans ethenyl group, a polymer obtained by polymerizing the hole transport material is highly amorph and forms a structural isomer. Thus, the temperature during curing is lowered and the reaction rate increases, which is advantageous.

The hole transport material may be a hole transport material in which the hole transport material represented by General Formula (1) above has another polymerizable group instead of the bifunctional vinyl group at the terminal end. Examples of such a hole transport material include, but are not limited to, Compound No. 14 below, which includes an oxetane group and a substituent (bivalent group).

The hole transport material may be a hole transport material not having a pyridine group, or may be the hole transport material represented by General Formula (1) above in which the pyridine group is substituted with a phenyl group. Examples of such a hole transport material include, but are not limited to, Compound No. 15 illustrated below.

Further, the hole transport material may have three functional polymerizable groups at the terminal ends, and examples of such a hole transport material include, but are not limited to, Compound No. 16 illustrated below.

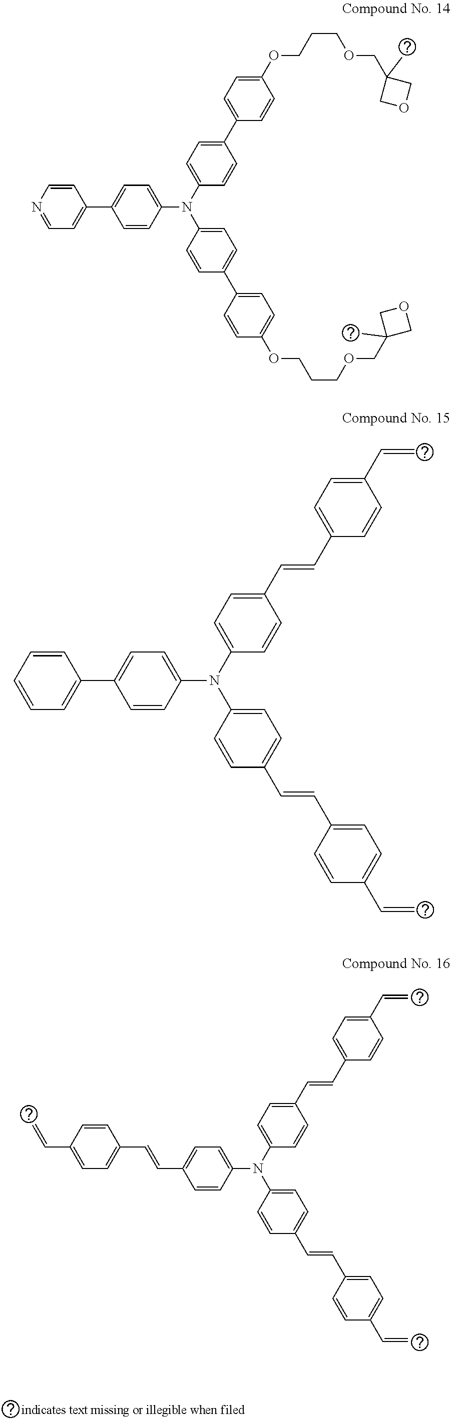

Suitable examples of the hole transport material include the hole transport material represented by General Formula (2).

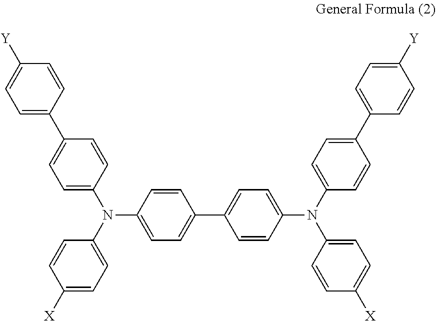

In General Formula (2) above, each X independently represents a polymerizable group that may include a substituent, and each Y independently represents a group selected from the group consisting of an alkoxy group and a pyridine group that may have a substituent.

The polymerizable group of X can be appropriately selected from the above-mentioned polymerizable groups, and is preferably an oxetane group, an epoxy group, a vinyl group, a vinyl ether group, an acrylate group, or a methacrylate group.

The substituent for X may be, for example, a monovalent group or a divalent group. Examples of the substituent include, but are not limited to, alkyl groups such as a methyl group and an ethyl group; alkylene groups such as a methylene group and an ethylene group; and oxyalkylene groups such as an oxymethylene group and an oxyethylene group.

Suitable examples of the substituent for Y include, but are not limited to, divalent groups such as alkylene groups including a methylene group and an ethylene group; and arylene groups including a phenylene group and a naphthylene group. The arylene group may include a substituent, and examples of the substituent include, but are not limited to, an alkyl group such as a methyl group and an ethyl group.

Examples of the alkoxy group of Y include, but are not limited to, a methoxy group and an ethoxy group.

Examples of the hole transport material represented by General Formula (2) above include, but are not limited to, Compounds No. 17 to No. 20 below.

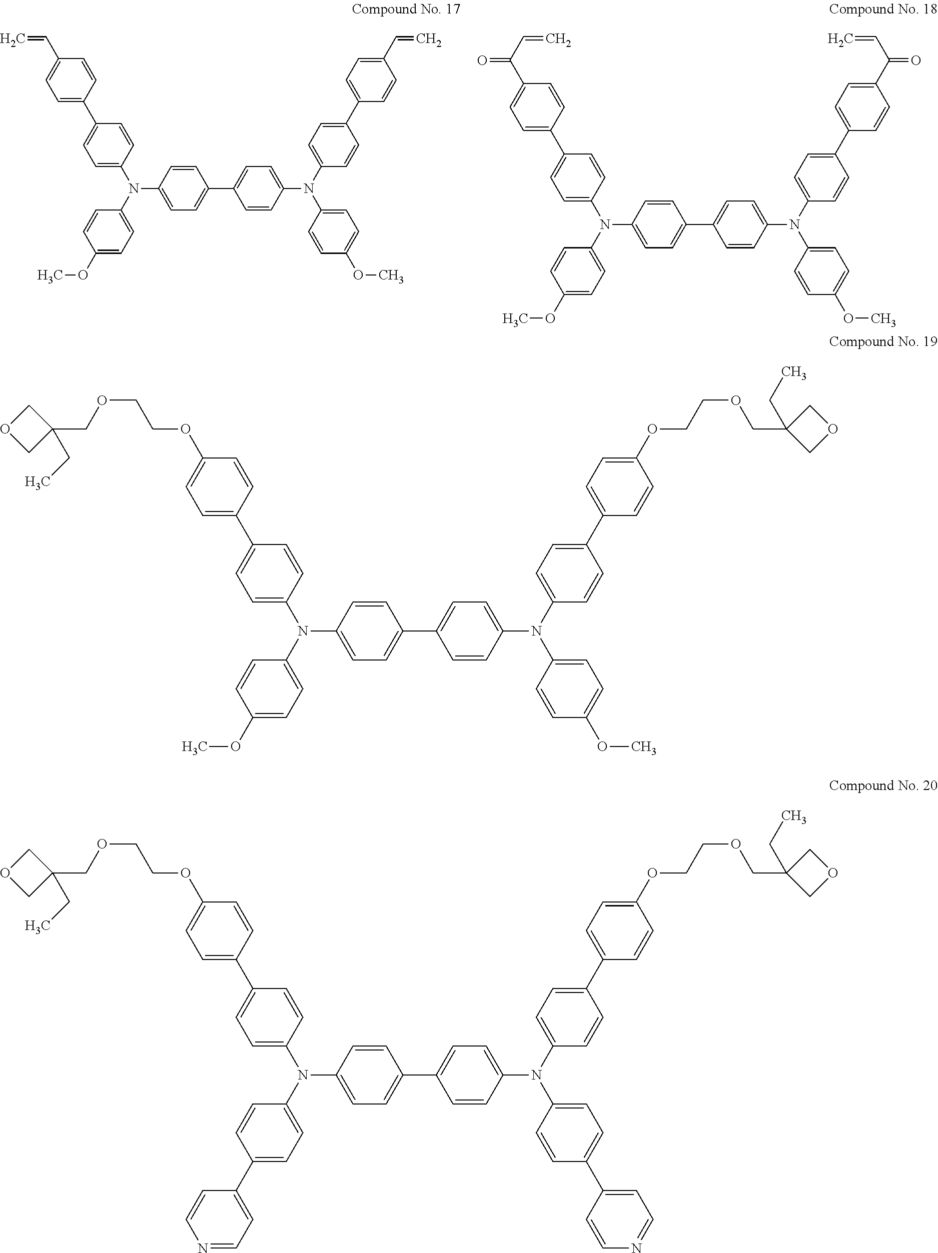

The hole transport layer can be formed by applying, onto the first electrode, a liquid composition containing the hole transport material, a solvent, and further, if desired, other components such as a polymerization initiator.

### —Solvent—

The solvent is not particularly limited, can be appropriately selected according to a purpose, and examples thereof include, but are not limited to, ketones, esters, ethers, amides, halogenated hydrocarbons, and hydrocarbons.

Examples of the ketones include, but are not limited to, acetone, methyl ethyl ketone, and methyl isobutyl ketone.

Examples of the esters include, but are not limited to, ethyl formate, ethyl acetate, and n-butyl acetate.

Examples of the ethers include, but are not limited to, diisopropyl ether, dimethoxyethane, tetrahydrofuran, dioxolane, and dioxane.

Examples of the amides include, but are not limited to, N,N-dimethylformamide, N,N-dimethylacetamide, and N-methyl-2-pyrrolidone.

Examples of the halogenated hydrocarbons include, but are not limited to, dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbons include, but are not limited to, n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These solvents may be used alone or in combination of two or more types.

### —Polymerization Initiator—

To promote the polymerization of General Formula (1) above, a polymerization initiator may be added.

Examples of the polymerization initiator include, but are not limited to, a thermal polymerization initiator that uses heat to initiate polymerization, and a photopolymerization initiator that uses light to initiate polymerization.

The thermal polymerization initiator is a compound that uses heat to generate active species such as radicals and cations. Specific examples of the thermal polymerization initiator include, but are not limited to, azo compounds such as 2,2′-azobisbutyronitrile (AIBN) and peroxides such as benzoyl peroxide (BPO). Examples of a thermal cationic polymerization initiator include, but are not limited to, benzenesulfonate esters and alkylsulfonium salts.

On the other hand, in the case of an epoxy resin, a cationic photopolymerization initiator is preferably used as the photopolymerization initiator. When an epoxy resin is mixed with a cationic photopolymerization initiator and irradiated with light, the cationic photopolymerization initiator decomposes to generate a strong acid. The acid induces polymerization of the epoxy resin and thus, the curing reaction progresses. The cationic photopolymerization initiator has little volumetric shrinkage during curing, is not inhibited by oxygen, and has high storage stability.

Examples of the cationic photopolymerization initiator include, but are not limited to, aromatic diazonium salts, aromatic iodonium salts, aromatic sulfonium salts, metallocene compounds, and silanol-aluminum complexes.

Further, a photoacid generator having a function of generating an acid in response to irradiation with light can also be used. The photoacid generator acts as an acid that initiates cationic polymerization. Examples of the photoacid generator include, but are not limited to, onium salts such as ionic sulfonium salts and iodonium salts that include a cationic moiety and an anionic moiety. More preferred examples of the photoacid generator include, but are not limited to, an ionic compound having a structure including an alkylamino group as the cationic moiety and a tetrakis(pentafluorophenyl)borate group as the anionic moiety. These photoacid generators may be used alone or in combination of two or more types.

The amount of the polymerization initiator to be added may vary depending on the material used. However, the amount of the polymerization initiator is preferably 0.5 parts by mass or more and 10 parts by mass or less, and more preferably 1 part by mass or more and 5 parts by mass or less, with respect to the total amount of 100 parts by mass of the sealing member. When the amount of the polymerization initiator being added is within the above-mentioned ranges, the curing proceeds appropriately, the remaining amount of uncured material can be reduced, and excessive outgassing can be prevented, which is effective.

A method of identifying the hole transport material and the hole transport layer is not particularly limited and may be appropriately selected according to a purpose. For example, a targeted hole transport material can be identified by using a Fourier transform infrared spectrometer (FT-IR) (for example, device name: IR TRACER-100, manufactured by Shimadzu Corporation).

In the hole transport layer, the hole transport material, which is a constituent component of the polymer of the hole transport material, exists as a residual monomer. Therefore, by identifying the remaining hole transport material, the constituent components of the polymer of the hole transport material can be identified.

In addition to the above-mentioned polymer of the hole transport material, the hole transport layer may contain a compound having the structural unit of General Formula (3) below and a compound represented by General Formula (4) below. By adding a dopant represented by General Formula (4), it is possible to obtain an effect of preventing a hole transport solution from forming a gel and reducing the resistance of a hole transport layer formed as a film by using ink.

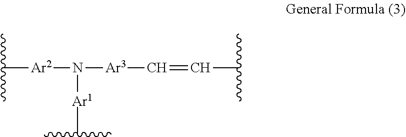

In General Formula (3) above, Ar¹ represents an aryl group. Examples of the aryl group include, but are not limited to, a phenyl group, a 1-naphthyl group, and a 9-anthracenyl group. The aryl group may have a substituent. Examples of the substituent include, but are not limited to, an alkyl group, an alkoxy group, and an aryl group. Ar² and Ar³ each independently represent an arylene group, a divalent heterocyclic group, or the like. Examples of the arylene group include, but are not limited to, 1,4-phenylene, 1,1′-biphenylene, and 9,9′-di-n-hexylfluorene. An example of the divalent heterocyclic group includes, but is not limited to, 2,5-thiophene.

A compound having the structural unit of General Formula (3) above is preferably a compound represented by General Formula (3A). Thus, it is possible to obtain an effect of reducing the resistance of the hole transport layer.

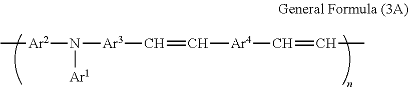

In General Formula (3A) above, Ar¹ represents an aromatic hydrocarbon group which may have a substituent.

Ar² and Ar³ each independently represent a divalent group of a monocyclic aromatic hydrocarbon group that may have a substituent, a non-condensed polycyclic aromatic hydrocarbon group that may have a substituent, or a condensed polycyclic aromatic hydrocarbon group that may have a substituent.

Ar⁴ represents a divalent group of benzene that may have a substituent, thiophene that may have a substituent, biphenyl that may have a substituent, anthracene that may have a substituent, or naphthalene that may have a substituent.

n represents an integer of 2 or more.

The weight average molecular weight of the polymer represented by General Formula (3A) above is preferably 2,000 or more.

In General Formula (3A) above, Ar¹ is an aromatic hydrocarbon group that may have a substituent. For example, Ar¹ represents an aryl group that may have a substituent.

Examples of the aryl group include, but are not limited to, a phenyl group, a 1-naphthyl group, and a 9-anthracenyl group. Examples of the substituent include, but are not limited to, an alkyl group, an alkoxy group, and an aryl group.

Ar² and Ar³ each independently represent a divalent group of a monocyclic aromatic hydrocarbon group that may have a substituent, a non-condensed polycyclic aromatic hydrocarbon group that may have a substituent, or a condensed polycyclic aromatic hydrocarbon group that may have a substituent. For example, Ar² and Ar³ each independently represent an arylene group that may have a substituent, a divalent heterocyclic group that may have a substituent, and the like. Examples of the arylene group include, but are not limited to, 1,4-phenylene, 1,1′-biphenylene, and 9,9′-di-n-hexylfluorene.

An example of the divalent heterocyclic group includes, but is not limited to, 2,5-thiophene. Examples of the substituent include, but are not limited to, an alkyl group, an alkoxy group, and an aryl group.

Ar⁴ represents a divalent group of benzene, thiophene, biphenyl, anthracene, or naphthalene, which may be substituted with a substituent. Examples of the substituent include, but are not limited to, an alkyl group, an alkoxy group, and an aryl group.

The compound represented by General Formula (3A) above is preferably a compound represented by General Formula (3B) below.

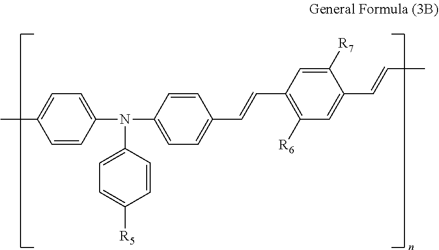

In General Formula (3B) above, R₅ represents a methyl group or a methoxy group, R₆ and R₇ represent an alkoxy group, and n represents an integer of 2 or more.

The weight average molecular weight of a compound (polymer) represented by General Formula (3) above is preferably 2,000 or more and 150,000 or less.

The weight average molecular weight can be measured by gel permeation chromatography (GPC).

Specific examples of the polymer represented by General Formula (3) above include, but are not limited to, Compounds (A-01) to (A-31) below.

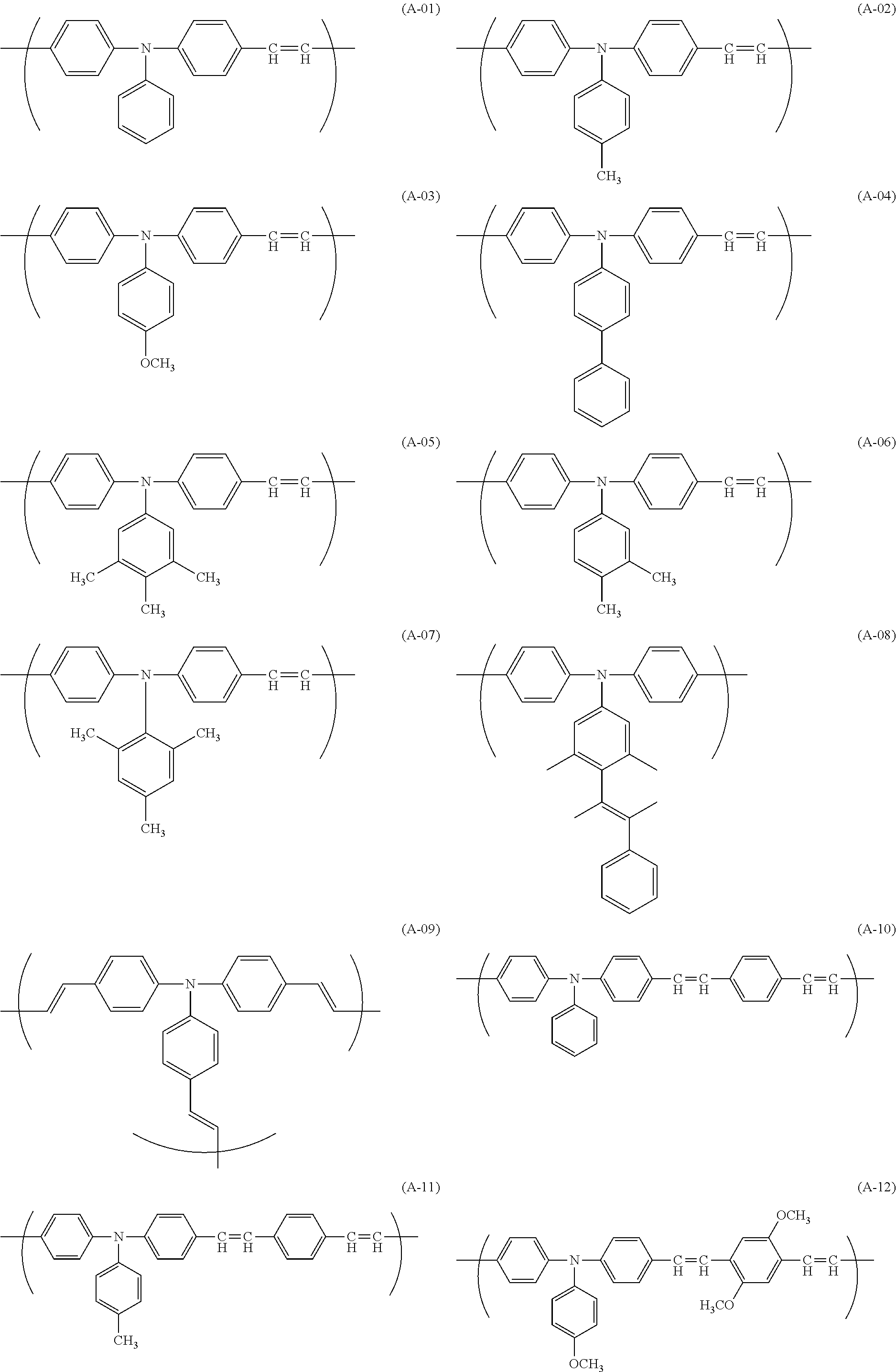

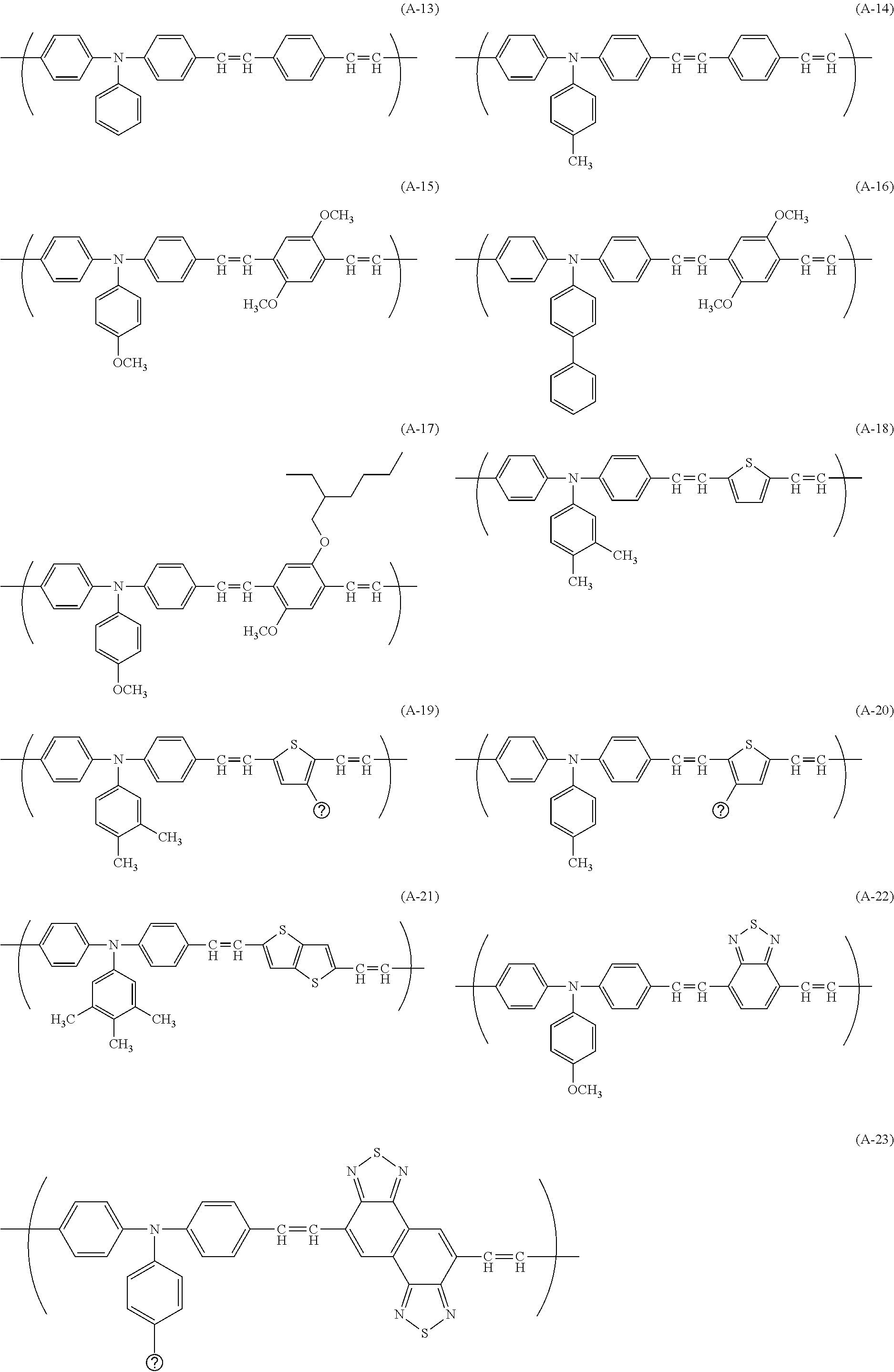

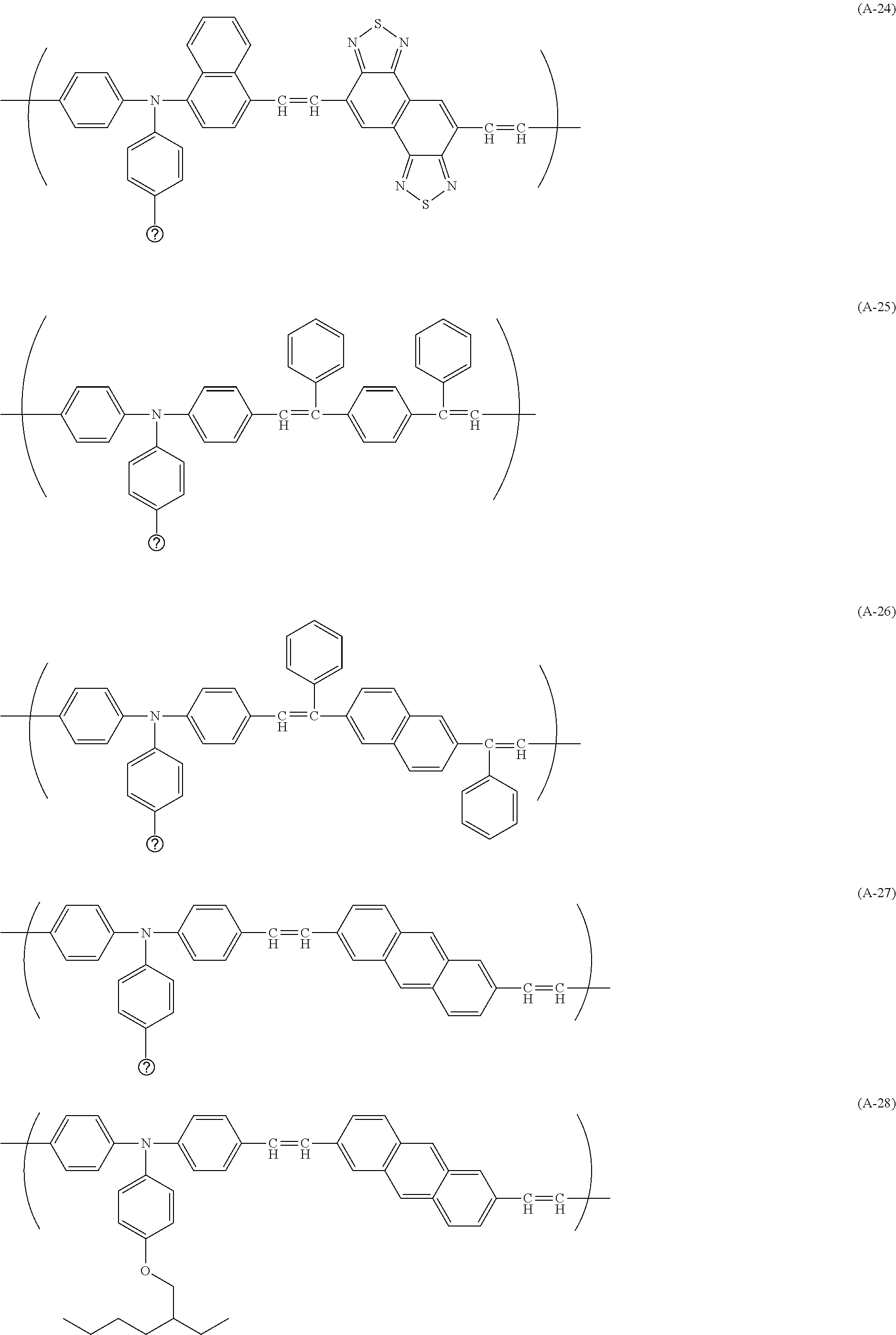

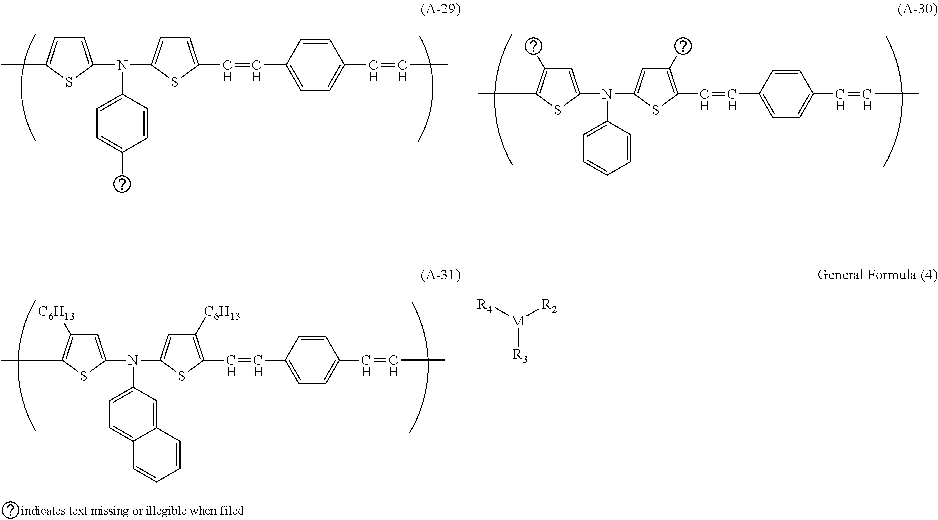

In General Formula (4) above, M represents any one element among boron, aluminum, phosphorus, and antimony. R₂, R₃, and R₄ each independently represent a hydrogen atom, a halogen atom, an alkyl group, an alkoxy group, an aryl group, a heteroaryl group, an ether bond, or an ester bond.

Examples of the halogen atom include, but are not limited to, a fluorine atom, a chlorine atom, a bromine atom, and an iodine atom.

Examples of the alkyl group include, but are not limited to, an alkyl group having 1 to 6 carbon atoms. The alkyl group may be substituted with a halogen atom.

Examples of the alkoxy group include, but are not limited to, an alkoxy group having 1 to 6 carbon atoms.

Examples of the aryl group include, but are not limited to, a phenyl group.

Specific examples of a compound represented by General Formula (4) above include, but are not limited to, Compounds (B-1) to (B-17) below.

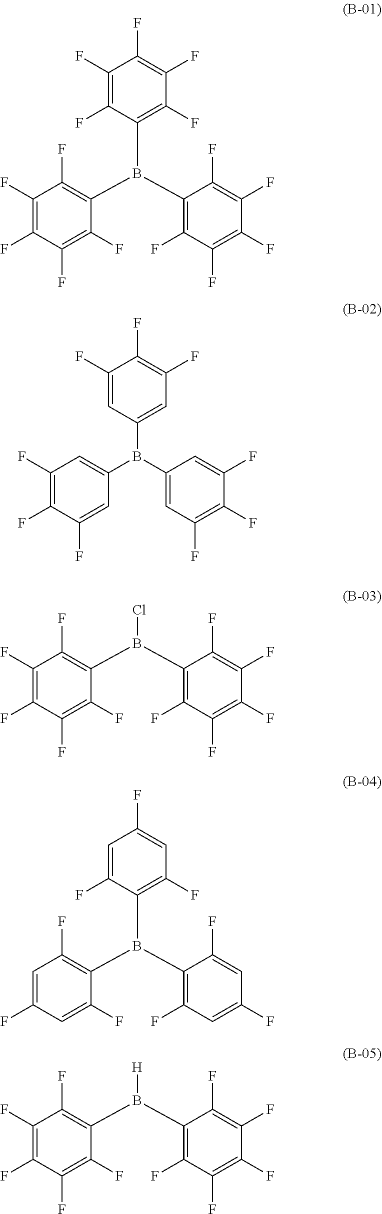

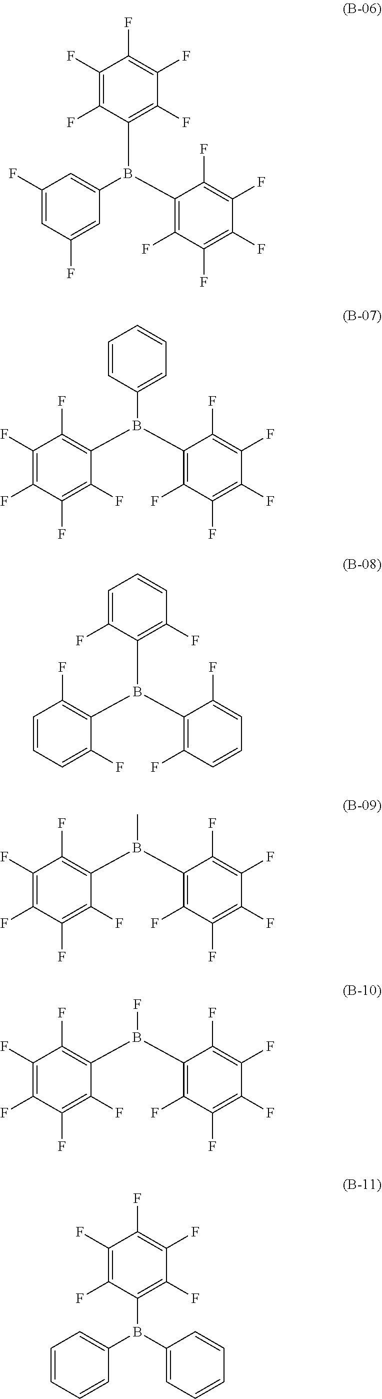

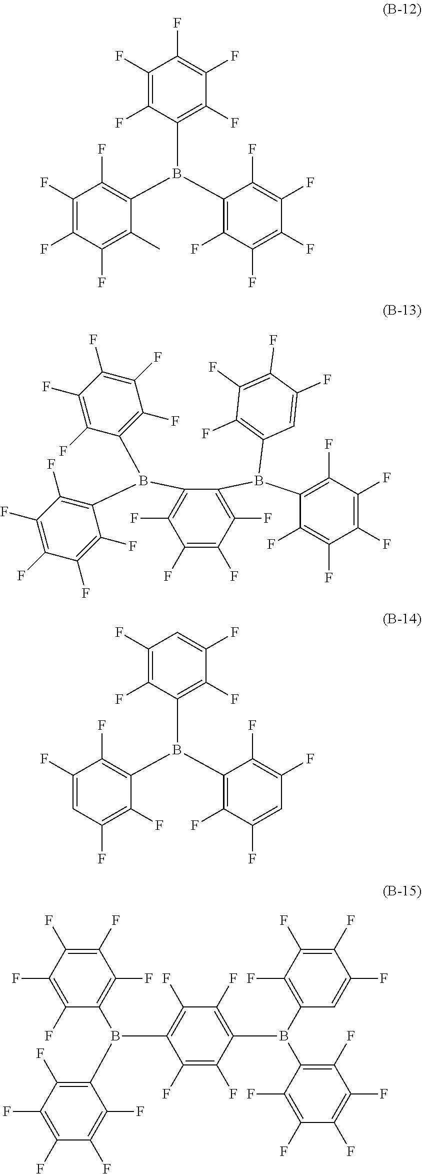

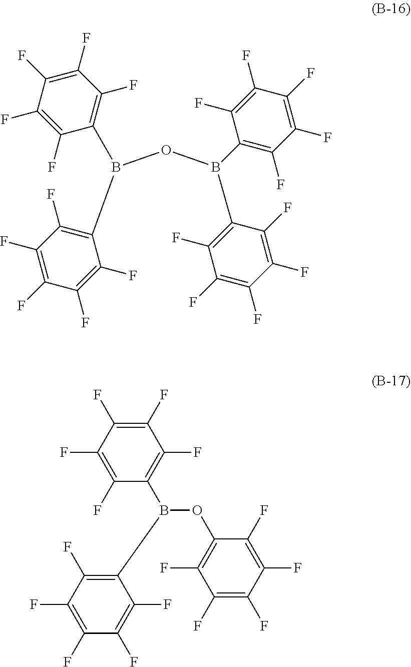

The hole transport layer may further include for example another solid hole transport material, and if desired, may include other materials.

The other solid hole transport material (may be simply referred to as “hole transport material” hereinafter) is not particularly limited and can be appropriately selected according to a purpose, as long as the other solid hole transport material is a material having a property by which holes are transported. However, the other solid hole transport material preferably contains an organic compound.

When an organic compound is used as the hole transport material, the hole transport layer contains, for example, a plurality of types of organic compounds.

Examples of the organic compound include, but are not limited to, a polymer material.

The polymer material used in the hole transport layer is not particularly limited and can be appropriately selected according to a purpose. Examples of the polymer material include, but are not limited to, polythiophene compounds, polyphenylene vinylene compounds, polyfluorene compounds, polyphenylene compounds, polyarylamine compounds, and polythiadiazole compounds.

Examples of the polythiophene compounds include, but are not limited to, poly(3-n-hexylthiophene), poly(3-n-octyloxythiophene), poly(9,9′-dioctyl-fluorene-co-bithiophene), poly(3,3″′-didodecyl-quaterthiophene), poly(3,6-dioctylthieno[3,2-b]thiophene), poly(2,5-bis(3-decylthiophene-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene).

Examples of the polyphenylene vinylene compounds include, but are not limited to, poly[2-methoxy-5-(2-ethylhexyloxy)-1,4-phenylene vinylene], poly[2-methoxy-5-(3,7-dimethyloctyloxy)-1,4-phenylene vinylene], and poly[(2-methoxy-5-(2-ethylhexyloxy)-1,4-phenylene vinylene)-co-(4,4′-biphenylene vinylene)].

Examples of the polyfluorene compounds include, but are not limited to, poly(9,9′-didodecylfluorenyl-2,7-diyl), poly[(9,9-dioctyl-2,7-divinylene fluorene)-alt-co-(9,10-anthracene)], poly[(9,9-dioctyl-2,7-divinylene fluorene)-alt-co-(4,4′-biphenylene)], poly[(9,9-dioctyl-2,7-divinylene fluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)].

Examples of the polyphenylene compounds include, but are not limited to, poly[2,5-dioctyloxy-1,4-phenylene] and poly[2,5-di(2-ethylhexyloxy-1,4-phenylene].

Examples of the polyarylamine compounds include, but are not limited to, poly[(9,9-dioctylfluorenyl-2,7-diyl)-alt-co-(N,N′-diphenyl)-N,N′-di(p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene].

Examples of the polythiadiazole compounds include, but are not limited to, poly[(9,9-dioctylfluorenyl-2,7-diyl)-alt-co-(1,4-benzo(2,1′,3)thiadiazole], and poly(3,4-didecylthiophene-co-(1,4-benzo(2,1′,3)thiadiazole).

Among these compounds, polythiophene compounds and polyarylamine compounds are preferred in consideration of carrier mobility and ionization potential.

The hole transport layer may contain not only the above-mentioned polymers, but also a compound having low molecular weight alone or a mixture of a compound having low molecular weight and a compound having high molecular weight.

An example of a chemical structure of a hole transport material having low molecular weight is not particularly limited. Examples of the hole transport material having low molecular weight include, but are not limited to, oxadiazole compounds, triphenylmethane compounds, pyrazoline compounds, hydrazone compounds, tetraarylbenzidine compounds, stilbene compounds, spirobifluorene compounds, and thiophene oligomers.

Examples of the oxadiazole compounds include, but are not limited to, the oxadiazole compounds described in Japanese Examined Patent Publication No. 34-5466 and Japanese Unexamined Patent Application Publication No. 56-123544.

Examples of the triphenylmethane compounds include, but are not limited to, the triphenylmethane compounds described in Japanese Examined Patent Publication No. 45-555.

Examples of the pyrazoline compounds include, but are not limited to, the pyrazoline compounds described in Japanese Examined Patent Publication No. 52-4188.

Examples of the hydrazone compounds include, but are not limited to, the hydrazone compounds described in Japanese Examined Patent Publication No. 55-42380.

Examples of the tetraarylbenzidine compounds include, but are not limited to, the tetraarylbenzidine compounds described in Japanese Unexamined Patent Application Publication No. 54-58445.

Examples of the stilbene compounds include, but are not limited to, the stilbene compounds described in Japanese Unexamined Patent Application Publication No. 58-65440 and Japanese Unexamined Patent Application Publication No. 60-98437.

Examples of the spirobifluorene compounds include, but are not limited to, the spirobifluorene compounds described in Japanese Unexamined Patent Application Publication No. 2007-115665A, Japanese Unexamined Patent Application Publication No. 2014-72327, Japanese Unexamined Patent Application Publication No. 2001-257012, WO2004/063283, WO2011/030450, WO2011/45321, WO2013/042699, and WO2013/121835.

Examples of the thiophene oligomers include, but are not limited to, the thiophene oligomers described in Japanese Unexamined Patent Application Publication No. 2-250881 and Japanese Unexamined Patent Application Publication No. 2013-033868.

When a polymer and a compound having low molecular weight are mixed, the difference in the ionization potentials of the polymer and the compound having low molecular weight is preferably 0.2 eV or less. The ionization potential is the energy required to remove one electron from a molecule, and is expressed in units of electron volts (eV).

A method of measuring the ionization potential is not particularly limited. However, the ionization potential is preferably measured by photoelectron spectroscopy.

Other materials contained in the hole transport layer are not particularly limited and can be appropriately selected according to a purpose. Examples of the other materials include, but are not limited to, additives and oxidizing agents.

The additives are not particularly limited and can be appropriately selected according to a purpose. Examples of the additives include, but are not limited to, iodine, metal iodides such as lithium iodide, sodium iodide, potassium iodide, cesium iodide, calcium iodide, copper iodide, iron iodide, and silver iodide, quaternary ammonium salts such as tetraalkylammonium iodide and pyridinium iodide, metal bromides such as lithium bromide, sodium bromide, potassium bromide, cesium bromide, and calcium bromide, bromide salts of quaternary ammonium compounds such as tetraalkylammonium bromide and pyridinium bromide, metal chlorides such as copper chloride and silver chloride, metal acetates such as copper acetate, silver acetate, and palladium acetate, metal sulfates such as copper sulfate and zinc sulfate, metal complexes such as ferrocyanide-ferricyanide and ferrocene-ferricinium ions, sulfur compounds such as sodium polysulfide and alkylthiol-alkyl disulfide, viologen dyes, hydroquinone, and basic compounds such as pyridine, 4-t-butylpyridine, and benzimidazole.

Further, an oxidizing agent may be added.

The oxidizing agent is not particularly limited and can be appropriately selected according to a purpose. Examples of the oxidizing agent include, but are not limited to, tris(4-bromophenyl)aminium hexachloroantimonate, silver hexafluoroantimonate, nitrosonium tetrafluoroborate, silver nitrate, cobalt complexes, and 4-isopropyl-4′-methyldiphenyliodonium tetrakis(pentafluorophenyl)borate. Not all of the hole transport material needs to be oxidized by the oxidizing agent, and an effect is achieved as long as a part of the hole transport material is oxidized. Further, the oxidizing agent may or may not be removed from the system after the reaction.

If the hole transport layer includes an oxidizing agent, a part or all of the hole transport material can be converted into radical cations. Therefore, it is possible to improve the conductivity and increase the durability and the stability of the output characteristics.

The average thickness of the hole transport layer is not particularly limited and may be appropriately selected according to a purpose. On the photoelectric conversion layer, the average thickness of the hole transport layer is preferably 0.01 μm or more and 20 μm or less, more preferably 0.1 μm or more and 10 μm or less, and even more preferably 0.2 μm or more and 2 μm or less.

The hole transport layer can be formed directly on the photoelectric conversion layer. A method of preparing the hole transport layer is not particularly limited and may be appropriately selected according to a purpose. Examples of the method include a method of forming a thin film in a vacuum such as by vacuum vapor deposition, and a wet film-forming method. Among these methods, in terms of production costs, the wet film-forming method is particularly preferred, and a method of coating a material on the photoelectric conversion layer to prepare the hole transport layer is more preferred.

The wet film-forming method is not particularly limited and can be appropriately selected according to a purpose. Examples of the wet film-forming method include a dipping method, a spraying method, a wire bar method, a spin coating method, a roller coating method, a blade coating method, a gravure coating method, and an inkjet method. Examples of wet printing methods include, but are not limited to, methods such as letterpress, offset, gravure, intaglio, rubber plate, and screen printing.

The hole transport layer may also be prepared by, for example, forming a film in a supercritical fluid or a subcritical fluid at a temperature and pressure lower than the critical point.

A supercritical fluid is a fluid that exists as a non-aggregating high-density fluid in a temperature and pressure region higher than the limit (critical point) at which gas and liquid can coexist, does not aggregate even when compressed, and is in a state where the temperature is at or higher than the critical temperature and the pressure is at or higher than the critical pressure. The supercritical fluid is not particularly limited and can be appropriately selected according to a purpose. However, it is preferable to use a fluid having a low critical temperature.

The subcritical fluid is not particularly limited and can be appropriately selected according to a purpose, as long as the subcritical fluid is a fluid existing as a high-pressure liquid in the temperature and pressure range near the critical point. The fluids mentioned as examples of the supercritical fluid can also be suitably used as the subcritical fluid.

Examples of the supercritical fluid include, but are not limited to, carbon monoxide, carbon dioxide, ammonia, nitrogen, water, alcohol solvents, hydrocarbon solvents, halogen solvents, and ether solvents.

Examples of the alcohol solvent include, but are not limited to, methanol, ethanol, and n-butanol.

Examples of the hydrocarbon solvents include, but are not limited to, ethane, propane, 2,3-dimethylbutane, benzene, and toluene. Examples of the halogen solvents include, but are not limited to, methylene chloride and chlorotrifluoromethane.

An example of the ether solvents includes, but is not limited to, dimethyl ether.

These supercritical fluids may be used alone or in combination of two or more types.

Among these supercritical fluids, carbon dioxide is preferred, because carbon dioxide has a critical pressure of 7.3 MPa and a critical temperature of 31° C. Therefore, carbon dioxide can be easily brought into a supercritical state, and is non-flammable and easy to handle.

The critical temperature and the critical pressure of the supercritical fluid are not particularly limited and can be appropriately selected according to a purpose. The critical temperature of the supercritical fluid is preferably −273° C. or higher and 300° C. or lower, and more preferably 0° C. or higher and 200° C. or lower.

Further, in addition to the supercritical fluid and the subcritical fluid, an organic solvent and an entrainer can also be used. By adding an organic solvent and an entrainer, the solubility in the supercritical fluid can be more easily adjusted.

The organic solvent is not particularly limited and can be appropriately selected according to a purpose. For example, the organic solvent can be appropriately selected from the solvents mentioned as examples of the solvent in the liquid composition of the present embodiment described above.

### <Photoelectric Conversion Layer>

The photoelectric conversion layer is not particularly limited and can be appropriately selected according to a purpose, as long as the photoelectric conversion layer is a layer that performs photoelectric conversion. Examples of the photoelectric conversion layer include, but are not limited to, a perovskite layer and a bulk heterojunction layer.

### <<Perovskite Layer>>

The perovskite layer refers to a layer that contains a perovskite compound and absorbs light to sensitize the electron transport layer. Therefore, the perovskite layer is preferably arranged adjacent to the electron transport layer.

The shape and the size of the perovskite layer are not particularly limited and can be appropriately selected according to a purpose.

The perovskite compound is a composite material of an organic compound and an inorganic compound, and is represented by General Formula (5) below.

X_{α}Y_{β}Z_{γ} General Formula (5)

In General Formula (5) above, a ratio of α:β:γ is 3:1:1, β and γ each represent an integer greater than 1, X represents a halogen atom, Y represents an organic compound having an amino group, and Z represents a metal ion.

In General Formula (5) above, X is not particularly limited and can be appropriately selected according to a purpose. Examples of X include, but are not limited to, halogen atoms such as chlorine, bromine, and iodine. These types of X may be used alone or in combination of two or more types.

In General Formula (5) above, Y is not particularly limited and can be appropriately selected according to a purpose, as long as Y is an organic cation. Examples of Y include, but are not limited to, ions of alkylamine compounds such as methylamine, ethylamine, n-butylamine, and formamidine, and inorganic alkali metal cations such as Sb atoms, Cs atoms, Rb atoms, and K atoms. These ions may be used alone or in combination of two or more types, and inorganic alkali metal cations and organic cations may be used in combination. Among these, organic compounds having an amino group are preferred.

Further, in the case of a methylammonium lead halide perovskite compound, peak λmax of the optical absorption spectrum shifts to the longer wavelength side in the following order. When the halogen ion is Cl, the peak λmax is about 350 nm, when the halogen ion is Br, the peak λmax is about 410 nm, and when the halogen ion is I, the peak λmax is about 540 nm. Therefore, the usable spectral width (band width) differs.

In General Formula (5), Z is not particularly limited and can be appropriately selected according to a purpose. Examples of Z include, but are not limited to, ions of metals such as lead, indium, antimony, tin, copper, and bismuth. These types of Z may be used alone or in combination of two or more types.

The perovskite layer preferably has a layered perovskite structure obtained by alternately laminating layers including a metal halide and layers in which organic cation molecules are arranged.

The average thickness of the perovskite layer is preferably 50 nm or more and 2 m or less, and more preferably 100 nm or more and 600 nm or less.

A method of forming the perovskite layer is not particularly limited and can be appropriately selected according to a purpose. An example of the method includes a method of applying a solution in which a metal halide, an alkylamine halide, a cesium halide, or the like is dissolved or dispersed, and then, the applied solution is dried.

Another example of a method of forming a perovskite layer includes a two-step precipitation method in which a solution obtained by dissolving or dispersing a metal halide is applied and dried, and then, the formed layer is immersed in a solution in which an alkylamine halide is dissolved, to form a perovskite compound.

Further, an example of a method of forming a perovskite layer includes a method in which a solution obtained by dissolving or dispersing a metal halide and an alkylamine halide is applied, while a poor solvent (a solvent having low solubility) for the perovskite compound is added to precipitate crystals.

In addition, an example of a method of forming a perovskite layer includes a method in which a metal halide is vapor-deposited in a gas filled with methylamine or the like.

Among these methods, a preferred method is to apply a solution in which a metal halide and an alkylamine halide are dissolved or dispersed, while adding a poor solvent for the perovskite compound to precipitate crystals.

A method of applying the solution is not particularly limited and can be appropriately selected according to a purpose. Examples of the method include an immersion method, a spin coating method, a spraying method, a dipping method, a roller method, an air knife method, and an inkjet method. An example of a method of applying the solution includes a method of precipitating the solution in a supercritical fluid using carbon dioxide or the like.

The perovskite layer may also contain a sensitizing dye.

A method of forming a perovskite layer containing the sensitizing dye is not particularly limited and can be appropriately selected according to a purpose. Examples of the method include, but are not limited to, a method of mixing a perovskite compound with a sensitizing dye, and a method of forming a perovskite layer and then adsorbing a sensitizing dye.

The sensitizing dye is not particularly limited and can be appropriately selected according to a purpose, as long as the sensitizing dye is a compound that can be photoexcited by the excitation light being used.

Examples of the sensitizing dye include, but are not limited to, metal complex compounds, coumarin compounds, polyene compounds, indoline compounds, thiophene compounds, cyanine dyes, merocyanine dyes, 9-arylxanthene compounds, triarylmethane compounds, phthalocyanine compounds, and porphyrin compounds.

Examples of the metal complex compounds include, but are not limited to, metal complex compounds described in Japanese Translation of PCT International Publication No. JP-T-7-500630, Japanese Unexamined Patent Application Publication No. 10-233238, Japanese Unexamined Patent Application Publication No. 2000-26487, Japanese Unexamined Patent Application Publication No. 2000-323191, and Japanese Unexamined Patent Application Publication No. 2001-59062.

Examples of the coumarin compounds include, but are not limited to, coumarin compounds described in Japanese Unexamined Patent Application Publication No. 10-93118, Japanese Unexamined Patent Application Publication No. 2002-164089, Japanese Unexamined Patent Application Publication No. 2004-95450, and J. Phys. Chem. C, 7224, Vol. 111 (2007).

Examples of the polyene compounds include, but are not limited to, the polyene compounds described in Japanese Unexamined Patent Application Publication No. 2004-95450 and Chem. Commun., 4887 (2007).

Examples of the indoline compounds include, but are not limited to, the indoline compounds described in Japanese Unexamined Patent Application Publication No. 2003-264010, Japanese Unexamined Patent Application Publication No. 2004-63274, Japanese Unexamined Patent Application Publication No. 2004-115636, Japanese Unexamined Patent Application Publication No. 2004-200068, Japanese Unexamined Patent Application Publication No. 2004-235052, J. Am. Chem. Soc., 12218, Vol. 126 (2004), Chem. Commun., 3036 (2003), and Angew. Chem. Int. Ed., 1923, Vol. 47 (2008).

Examples of the thiophene compounds include, but are not limited to, the thiophene compounds described in J. Am. Chem. Soc., 16701, Vol. 128 (2006) and J. Am. Chem. Soc., 14256, Vol. 128 (2006).

Examples of the cyanine dyes include, but are not limited to, the cyanine dyes described in Japanese Unexamined Patent Application Publication No. 11-86916, Japanese Unexamined Patent Application Publication No. 11-214730, Japanese Unexamined Patent Application Publication No. 2000-106224, Japanese Unexamined Patent Application Publication No. 2001-76773, and Japanese Unexamined Patent Application Publication No. 2003-7359.

Examples of the merocyanine dyes include, but are not limited to, merocyanine dyes described in Japanese Unexamined Patent Application Publication No. 11-214731, Japanese Unexamined Patent Application Publication No. 11-238905, Japanese Unexamined Patent Application Publication No. 2001-52766, Japanese Unexamined Patent Application Publication No. 2001-76775, and Japanese Unexamined Patent Application Publication No. 2003-7360.

Examples of the 9-arylxanthene compounds include, but are not limited to, the 9-arylxanthene compounds described in Japanese Unexamined Patent Application Publication No. 10-92477, Japanese Unexamined Patent Application Publication No. 11-273754, Japanese Unexamined Patent Application Publication No. 11-273755, and Japanese Unexamined Patent Application Publication No. 2003-31273.

Examples of the triarylmethane compounds include, but are not limited to, the triarylmethane compounds described in Japanese Unexamined Patent Application Publication No. 10-93118 and Japanese Unexamined Patent Application Publication No. 2003-31273.

Examples of the phthalocyanine compounds and the porphyrin compounds include, but are not limited to, the phthalocyanine compounds and the porphyrin compounds described in Japanese Unexamined Patent Application Publication No. 9-199744, Japanese Unexamined Patent Application Publication No. 10-233238, Japanese Unexamined Patent Application Publication No. 11-204821, Japanese Unexamined Patent Application Publication No. 11-265738, J. Phys. Chem., 2342, Vol. 91 (1987), J. Phys. Chem. B, 6272, Vol. 97 (1993), Electroanal. Chem., 31, Vol. 537 (2002), Japanese Unexamined Patent Application Publication No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008).

Among these compounds, metal complex compounds, indoline compounds, thiophene compounds, and porphyrin compounds are preferred.

### <Electron Transport Layer>

The electron transport layer refers to a layer that transports electrons generated in a photoelectric conversion layer, which will be described later, to an electrode. Therefore, the electron transport layer is preferably arranged adjacent to the second electrode.

The shape and the size of the electron transport layer are not particularly limited and can be appropriately selected according to a purpose.

The electron transport layer may have a single layer structure or a multilayer structure in which a plurality of layers are laminated.

The electron transport layer contains an electron transport material.

The electron transport material is not particularly limited and can be appropriately selected according to a purpose. However, the electron transport material is preferably a semiconductor material.

The semiconductor material is not particularly limited, and any known material can be used as the semiconductor material. Examples of the semiconductor material include, but are not limited to, an elemental semiconductor and a compound including a compound semiconductor.

Examples of the elemental semiconductor include, but are not limited to, silicon and germanium.

Examples of the compound semiconductor include, but are not limited to, metal chalcogenides.

Examples of the metal chalcogenides include, but are not limited to, metal oxides (oxide semiconductors), metal sulfides, metal selenides, and metal tellurides.

Examples of the metal oxides (oxide semiconductors) include, but are not limited to, oxides of titanium, tin, zinc, iron, tungsten, zirconium, hafnium, strontium, indium, cerium, yttrium, lanthanum, vanadium, niobium, and tantalum.

Examples of the metal sulfides include, but are not limited to, sulfides of cadmium, zinc, lead, silver, antimony, and bismuth.

Examples of metal selenides include, but are not limited to, selenides of cadmium and lead.

Examples of the metal tellurides include, but are not limited to, tellurides of cadmium.

Examples of other compound semiconductors include, but are not limited to, phosphides of zinc, gallium, indium, and cadmium, gallium arsenide, copper-indium-selenide, and copper-indium-sulfide.

Among the semiconductor materials, metal oxides (oxide semiconductors) are preferred, at least one of titanium oxide, zinc oxide, tin oxide, and niobium oxide is more preferred, and tin oxide is even more preferred.

These semiconductor materials may be used alone or in combination of two or more types. The crystal type of the semiconductor material is not particularly limited and can be appropriately selected according to a purpose. The semiconductor material may be a single crystal, polycrystalline, or amorphous.

The electron transport layer preferably contains, on the electron transport material on the surface on the side of the photoelectric conversion layer, at least one compound from among a phosphonic acid compound, a boronic acid compound, a sulfonic acid compound, a halogenated silyl compound, and an alkoxysilyl compound. The electron transport layer contains these compounds on the electron transport material on the surface on the side of the photoelectric conversion layer. If the electron transport layer contains these compounds, it is expected that the physical properties of the interface between the electron transport layer and the photoelectric conversion layer can be controlled. In other words, by applying these compounds onto the electron transport material on the surface of the electron transport layer on the side of the photoelectric conversion layer, it is expected that the interfacial resistance between the electron transport layer and the photoelectric conversion layer decreases, and the electron transfer is made smoother.

These compounds may be bonded to the electron transport material. Examples of the bond include, but are not limited to, a covalent bond and an ionic bond.

The compound is at least one compound among a phosphonic acid compound, a boronic acid compound, a sulfonic acid compound, a halogenated silyl compound, and an alkoxysilyl compound.

The compound preferably contains a nitrogen atom to ensure compatibility with the photoelectric conversion layer (perovskite layer) described below.

The phosphonic acid compound is not particularly limited and can be appropriately selected according to a purpose, as long as the phosphonic acid compound is a compound containing a phosphonic acid group. Specific examples of the phosphonic acid compound will be described later.

The boronic acid compound is not particularly limited and can be appropriately selected according to a purpose, as long as the boronic acid compound is a compound containing a boronic acid group. Specific examples of the boronic acid compound will be described later.

The sulfonic acid compound is not particularly limited and can be appropriately selected according to a purpose, as long as the sulfonic acid compound is a compound containing a sulfonic acid group. Specific examples of the sulfonic acid compound will be described later.

The halogenated silyl compound is not particularly limited and can be appropriately selected according to a purpose, as long as the halogenated silyl compound is a compound containing a halogenated silyl group. Specific examples of the halogenated silyl compound will be described later.

The alkoxysilyl compound is not particularly limited and can be appropriately selected according to a purpose, as long as the alkoxysilyl compound is a compound containing an alkoxysilyl group. Specific examples of the alkoxysilyl compound will be described later.

The molecular weight of the compound is not particularly limited and can be appropriately selected according to a purpose. For example, the molecular weight may be 100 or more and 500 or less.

For example, the compound is represented by General Formula (X) below.

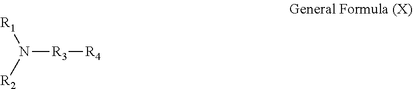

In General Formula (X) above, R₁ and R₂ represent a hydrogen atom, an alkyl group, an aryl group, or a heterocycle, and may be the same or may be different. R₃ represents a divalent alkylene group, a divalent aryl group, or a divalent heterocycle. R₄ represents a phosphonic acid group, a boronic acid group, a sulfonic acid group, a halogenated silyl group, or an alkoxysilyl group. R₁ or R₂, R₃, and N may be joined together to form a ring structure.

Examples of the compound include, but are not limited to, Compounds (X-01) to (X-56) below.

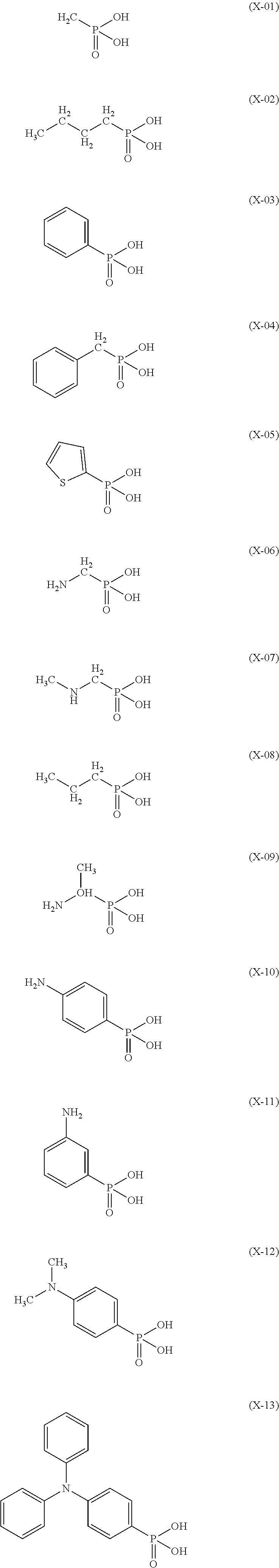

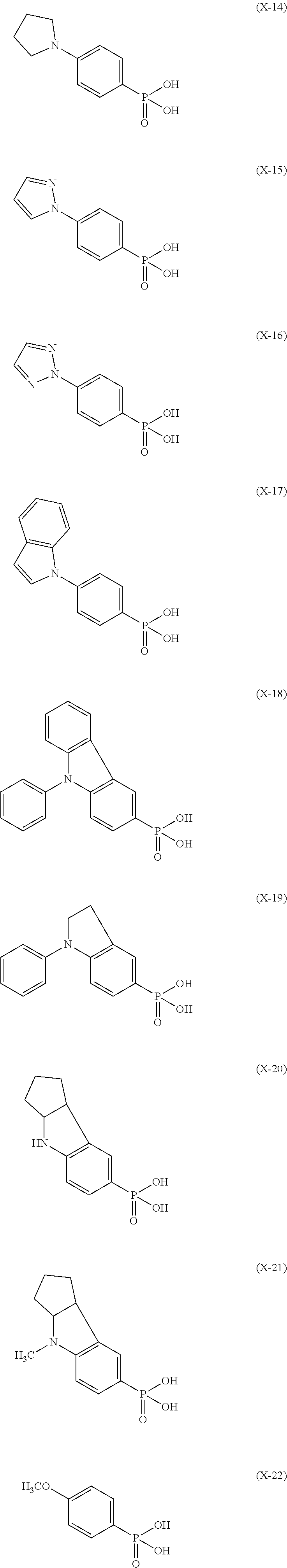

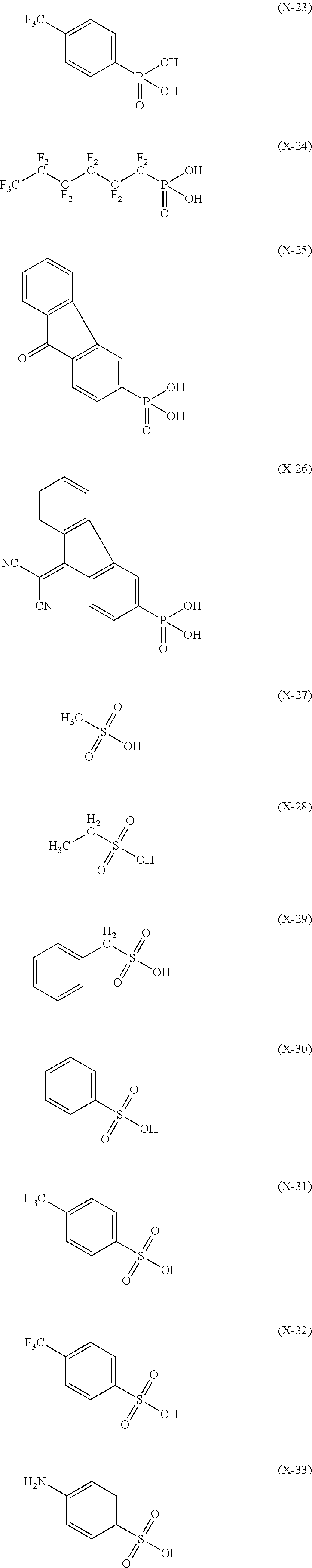

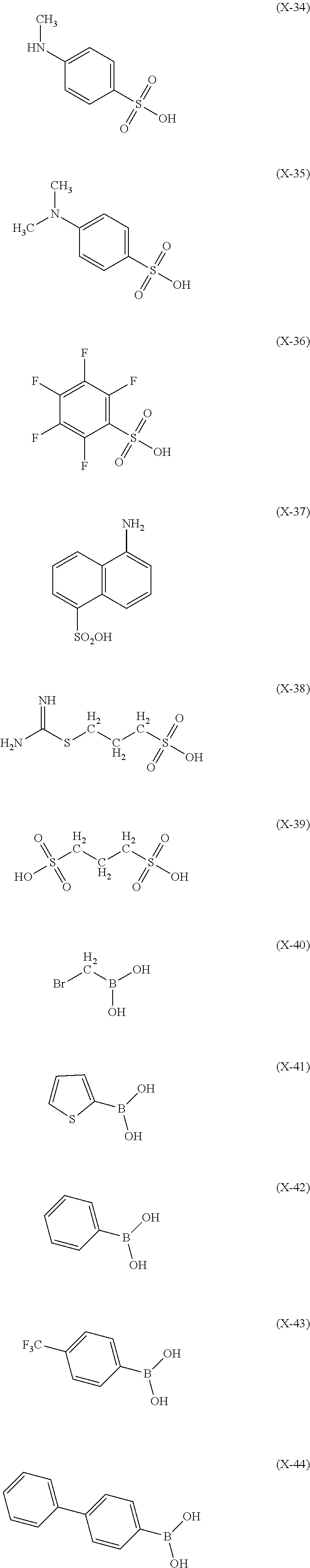

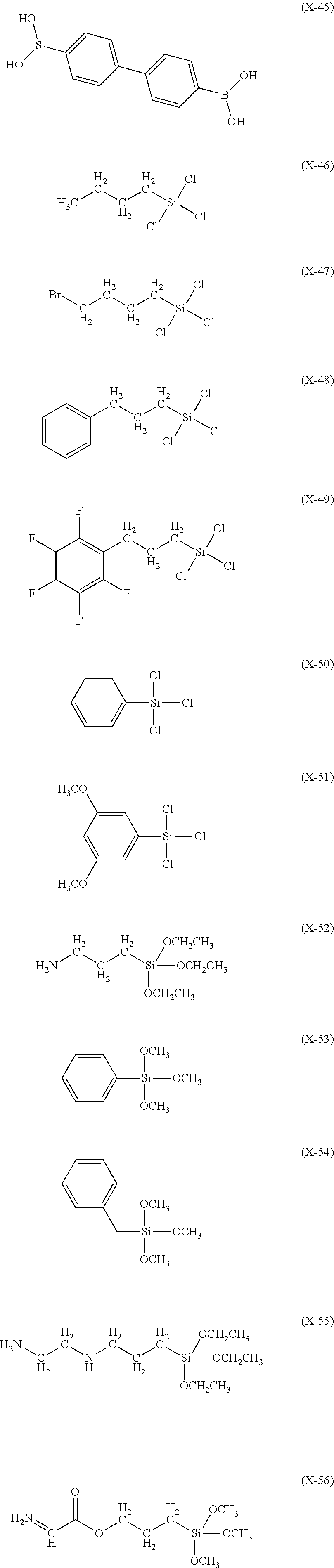

It is preferable to coat the surface of the metal oxide on the electron transport layer with a compound including a substituent that reacts with the metal oxide, such as a phosphonic acid, a sulfonic acid, or a halogenated silyl group.

Specific examples of the compound used for coating the surface include, but are not limited to, methylphosphonic acid, phenylphosphonic acid, phenethylphosphonic acid, (1-aminoethyl)phosphonic acid, (2-aminoethyl)phosphonic acid, methanesulfonic acid, benzenesulfonic acid, 2-thienylboronic acid, methyltrichlorosilane, and n-hexyltriethoxysilane.

The average thickness of the electron transport layer is not particularly limited and may be appropriately selected according to a purpose, but is preferably 5 nm or more and 1 μm or less, and more preferably 10 nm or more and 700 nm or less.

The surface of the electron transport layer on the side of the photoelectric conversion layer is preferably as smooth as possible. The roughness factor, which serves an indicator expressing the smoothness, is preferably small. In relation to the average thickness of the electron transport layer, the roughness factor of the electron transport layer on the side of the photoelectric conversion layer side is preferably 20 or less, and more preferably 10 or less. A lower limit value of the roughness factor is not particularly limited and can be appropriately selected according to a purpose. For example, the lower limit value may be 1 or more.

The roughness factor is the ratio of the actual surface area to the apparent surface area, and is also called the Wenzel roughness factor. The actual surface area can be measured, for example, by measuring the BET specific surface area. The roughness factor can be determined by dividing the value of the BET specific surface area by the apparent surface area.

A method of preparing a thin film of the electron transport material in the electron transport layer is not particularly limited and can be appropriately selected according to a purpose. Examples of the method include a wet film-forming method and method of forming a thin film of the electron transport material in a vacuum (vacuum film-forming method).

Examples of the vacuum film-forming method include, but are not limited to, a sputtering method, a pulsed laser deposition method (PLD method), an ion beam sputtering method, an ion-assisted method, an ion plating method, a vacuum vapor deposition method, an atomic layer deposition method (ALD method), and a chemical vapor deposition method (CVD method).

An example of the wet film-forming method includes, but is not limited to, a sol-gel method. The sol-gel method is a method in which a gel is prepared from a solution by a chemical reaction such as hydrolysis and polymerization/condensation, and then, a heat treatment is performed to promote densification. When a sol-gel method is used, a method of applying a sol solution is not particularly limited and can be appropriately selected according to a purpose. Examples of the method include a dipping method, a spraying method, a wire bar method, a spin coating method, a roller coating method, a blade coating method, a gravure coating method, and an inkjet method. Examples of wet printing methods include letterpress, offset, gravure, intaglio, rubber plate, and screen printing. The temperature during the heat treatment after the application of the sol solution is preferably 80° C. or higher, and more preferably 100° C. or higher.

A method of applying the compound onto the electron transport material is not particularly limited and can be appropriately selected according to a purpose. Examples of the method include a method in which a solution containing the compound is applied onto a thin film of the electron transport material and then, the applied solution is dried.

The coating method is not particularly limited and may be appropriately selected according to a purpose. Examples of the coating method include a dipping method, a spraying method, a wire bar method, a spin coating method, a roller coating method, a blade coating method, and a gravure coating method.

The temperature during the drying process after the solution is applied is preferably 40° C. or higher, and more preferably 50° C. or higher.

Further, after laminating the electron transport layer on the photoelectric conversion layer, a pressing process step may be implemented. By the pressing process, the electron transport layer and the hole transport layer adhere more closely to the photoelectric conversion layer, and thus, it is possible to improve the power generation efficiency.

A method used in the pressing process is not particularly limited and can be appropriately selected according to a purpose. Examples of the method include a press molding method using a flat plate such as an infrared (IR) spectroscopy tablet molding machine, and a roll press method using a roller.

The pressure during the pressing process is preferably 10 kgf/cm² or more, and more preferably 30 kgf/cm² or more.

The time used for the pressing process is not particularly limited and can be appropriately selected according to a purpose, but is preferably 1 hour or less. Heat may also be applied during the pressing process.

During the pressing process, a release agent may be sandwiched between the pressing machine and the electrode.

The release agent is not particularly limited and can be appropriately selected according to a purpose. Examples of the release agent include, but are not limited to, fluororesins such as polytetrafluoroethylene, polychlorotrifluoroethylene, a tetrafluoroethylene-hexafluoropropylene copolymer, a perfluoroalkoxy fluoride resin, polyvinylidene fluoride, an ethylene-tetrafluoroethylene copolymer, an ethylene-chlorotrifluoroethylene copolymer, and polyvinyl fluoride. These release agents may be used alone or in combination of two or more types.

### <Passivation Layer>

The inverted structure-type photoelectric conversion element preferably further includes a passivation layer between the photoelectric conversion layer and the electron transport layer.

The passivation layer preferably contains an amine compound different from the compound contained in the photoelectric conversion layer, and preferably contains a compound represented by General Formula (6) below.

A-X General Formula (6)

In General Formula (6) above, A is at least one compound among an amino cation compound, a pyridinium cation compound, an imidazolinium cation compound, and a pyrrolidinium cation compound represented by any one of General Formula (7) below and General Formula (8) below. X represents a halogen ion.

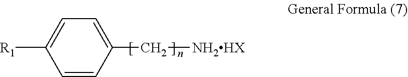

In General Formula (7) above, R₁ represents any one among —H, —F, —CF₃, and —OCH₃, n represents 1 or 2, and X represents any one of Br and I.

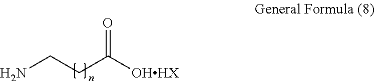

In General Formula (8) above, n represents an integer of 3 or more and 12 or less, and X represents any one of Br and I.

Specific examples of compounds represented by General Formula (7) above include, but are not limited to, (E-1) to (E-12) indicated below. However, the compound is not limited thereto.

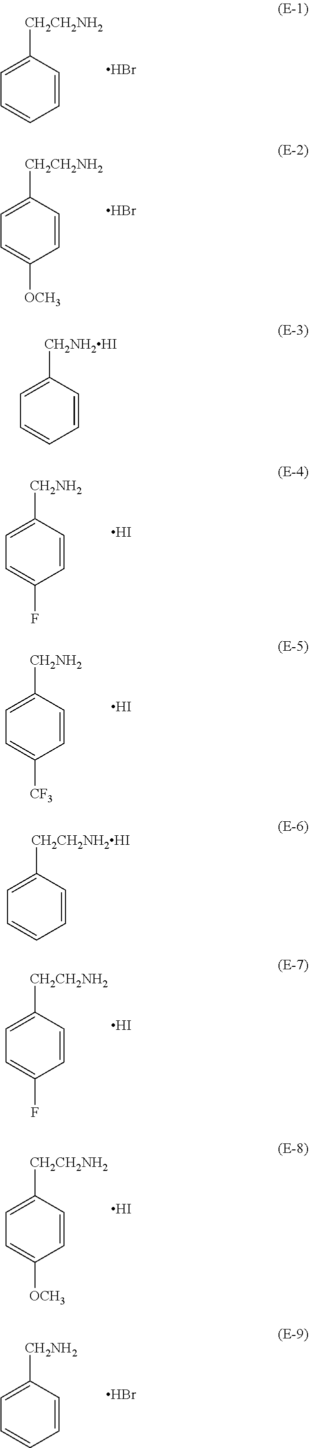

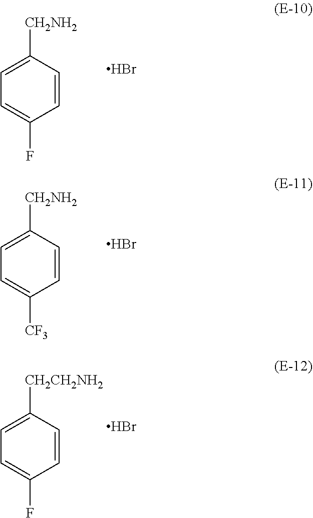

Specific examples of compounds represented by General Formula (8) above include, but are not limited to, 5-aminopentanoic acid hydroiodide, 5-aminopentanoic acid hydrobromide, 6-aminohexanoic acid hydroiodide, 6-aminohexanoic acid hydrobromide, 7-aminoheptanoic acid hydroiodide, 7-aminoheptanoic acid hydrobromide, 8-aminoheptanoic acid hydroiodide, 8-aminoheptanoic acid hydrobromide, 9-aminononanoic acid hydroiodide, 9-aminononanoic acid hydrobromide, 10-aminodecanoic acid hydroiodide, 10-aminodecanoic acid hydrobromide, 11-aminoundecanoic acid hydroiodide, 12-aminoundecanoic acid hydrobromide, 12-aminododecanoic acid hydroiodide, and 12-aminododecanoic acid hydrobromide.

The photoelectric conversion element includes the passivation layer between the photoelectric conversion layer and the hole transport layer, and thus, it is expected that the physical properties of the interface can be controlled.

Note that, when the photoelectric conversion layer is a perovskite layer, the compound (organic salt or inorganic salt) represented by General Formula (6) above is preferably a salt different from the salt included in the perovskite layer.

The salt is not particularly limited and can be appropriately selected according to a purpose. However, in particular when a perovskite compound is used in the photoelectric conversion layer, the salt preferably contains a halogen atom to ensure compatibility. Examples of the halogen atoms include, but are not limited to, chlorine, iodine, and bromine.

In particular, when a perovskite compound is used in the photoelectric conversion layer, the organic salt is preferably a hydrogen halide salt of amine to ensure compatibility.

In particular, when a perovskite compound is used in the photoelectric conversion layer, the inorganic salt is preferably a halide of an alkali metal to ensure compatibility. Examples of the alkali metal include, but are not limited to, lithium, sodium, potassium, rubidium, and cesium.

The above-mentioned A is at least one compound among an amino cation compound, a pyridinium cation compound, an imidazolinium cation compound, and a pyrrolidinium cation compound represented by any one of General Formula (7) below and General Formula (8) below.

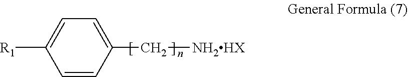

In General Formula (7) above, R₁ represents any one among —H, —F, —CF₃, and —OCH₃, n represents 1 or 2, and X represents any one of Br and I.

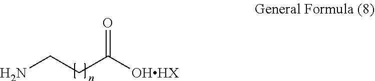

In General Formula (8) above, n represents an integer of 3 or more and 12 or less, and X represents any one of Br and I.

Examples of X in General Formula (6) above include, but are not limited to, halogen anions such as a bromine (Br) anion and an iodine (I) anion.

A method of forming the passivation layer between the photoelectric conversion layer and the electron transport layer is not particularly limited and can be appropriately selected according to a purpose. An example of the method includes a method in which a solution containing a compound (an organic salt or an inorganic salt) represented by General Formula (6) above is applied onto the photoelectric conversion layer, the solution is dried, and then, an electron transport layer is further formed thereon.

Examples of the solution include, but are not limited to, an aqueous solution and an alcohol.

The coating method is not particularly limited and can be appropriately selected according to a purpose. Examples of the coating method include a dipping method, a spraying method, a wire bar method, a spin coating method, a roller coating method, a blade coating method, a gravure coating method, and an inkjet method.

An example of a method of applying the solution includes a method of precipitating the solution in a supercritical fluid using carbon dioxide or the like. The film thickness of the layer is not limited, and the solution may be adsorbed by single molecules or may be in the form of islands that are not continuous.

The temperature during the drying process after the solution is applied is not particularly limited and can be appropriately selected according to a purpose.

The average thickness of the passivation layer is preferably 0.5 nm or more and 100 nm or less, and more preferably 1 nm or more and 50 nm or less.

The compound (organic salt or inorganic salt) represented by General Formula (6) above does not need to be uniformly distributed at the interface between the photoelectric conversion layer and the hole transport layer, and may be present locally in a plurality of regions (for example, in the form of islands). When the photoelectric conversion layer is a perovskite layer, the perovskite compound may be reacted with the hole transport material of the hole transport layer to distribute the compound represented by General Formula (6) above in the perovskite layer or the hole transport layer. That is, it is only required to provide a region in which the compound (organic salt or inorganic salt) represented by General Formula (6) above is present between the perovskite layer in which the compound (organic salt or inorganic salt) represented by General Formula (6) above is not present and the hole transport layer in which no organic salt and inorganic salt is present.

### <Second Electrode>

The second electrode is not particularly limited and can be appropriately selected according to a purpose.

In one embodiment, the second electrode preferably contains a metal nanowire. Thus, both the first electrode and the second electrode are transparent electrodes, and the infrared light transmittance of the photoelectric conversion element is good.

The second electrode may be formed on the electron transport layer.

The second electrode does not necessarily require a support body, as long as the strength and the sealability are sufficiently maintained.

The second electrode can be appropriately formed on the electron transport layer by coating, lamination, vapor deposition, CVD, bonding, or other techniques, depending on the type of material being used and the type of the electron transport layer.

The structure of the second electrode is not particularly limited and can be appropriately selected according to a purpose. The structure may be a single-layer structure or a structure in which a plurality of materials are laminated.

The material of the second electrode is not particularly limited and can be appropriately selected according to a purpose, as long as the material has conductivity. Examples of the material include, but are not limited to, transparent conductive metal oxides, carbon, and metals.

Examples of the transparent conductive metal oxides include, but are not limited to, indium tin oxide (hereinafter referred to as “ITO”), fluorine-doped tin oxide (hereinafter referred to as “FTO”), antimony-doped tin oxide (hereinafter referred to as “ATO”), niobium-doped tin oxide (hereinafter referred to as “NTO”), aluminum-doped zinc oxide (hereinafter referred to as “AZO”), indium zinc oxide, and niobium titanium oxide.

Examples of the types of carbon include, but are not limited to, carbon black, carbon nanotubes, graphene, and fullerene.

Examples of the metals include, but are not limited to, gold, silver, aluminum, nickel, indium, tantalum, and titanium.

These metals may be used alone or in combination of two or more types. Among these materials, transparent conductive metal oxides having high transparency are preferred, and ITO, FTO, ATO, NTO, and AZO are more preferred.

The average thickness of the second electrode is not particularly limited and may be appropriately selected according to a purpose, but is preferably 5 nm or more and 100 μm or less, and more preferably 50 nm or more and 10 μm or less. When the material of the second electrode includes carbon or a metal, the average thickness of the second electrode is preferably set to an average thickness at which it is possible to obtain light transmittance.

The second electrode can be formed by a known method such as a die coating method, a spin coating method, a sputtering method, a vapor deposition method, and a spraying method.

### <Sealing Member>

In the photoelectric conversion element, it is possible and effective to use a sealing member that can shield at least the electron transport layer and the hole transport layer from the external environment of the photoelectric conversion element. In other words, in the present embodiment, it is preferable to further provide a sealing member that shields the photoelectric conversion layer from the external environment of the photoelectric conversion element.

Any member known in the related art can be used as the sealing member, as long as the member can reduce the intrusion of excess moisture, oxygen, and the like from the external environment into the sealed interior. Further, the sealing member has an effect of preventing mechanical damage caused when the photoelectric conversion element is pressed from the outside, and any member known in the related art can be used as the sealing member, as long as the member can achieve this effect.

Sealing methods can be broadly divided into “frame sealing” and “surface sealing”. In the “frame sealing”, a sealing member is provided in a peripheral edge portion of a power generation region, which is formed by the photoelectric conversion layer of the photoelectric conversion element, and then, the sealing member is adhered to the second substrate. In the “surface sealing”, a sealing member is provided on the entire surface of the power generation region and then, adhered to the second substrate. By the former-mentioned “frame sealing”, a hollow portion can be formed inside the sealed interior, and thus, it is possible to appropriately adjust the amount of moisture and the amount of oxygen in the sealed interior. Further, the “frame sealing” provides an effect of reducing the impact of electrode peeling, because the second electrode does not contact the sealing member. On the other hand, the latter-mentioned “surface sealing” is highly effective in preventing the intrusion of excess water and oxygen from the outside. The area in which the sealing member and the second substrate adhere to each other is large, and thus, the sealing strength is high, and the “surface sealing” is particularly suitable when a flexible substrate is used as the first substrate.

The type of the sealing member is not particularly limited and can be appropriately selected according to a purpose. For example, a cured resin or a glass resin having a low melting point can be used as the sealing member. The cured resin is not particularly limited and can be appropriately selected according to a purpose, as long as the cured resin is a resin that is cured by light or heat. However, among these resins, acrylic resins and epoxy resins are preferably used.

As a cured product of the acrylic resin, any known material can be used, as long as the material is a cured material of a monomer or an oligomer having an acrylic group in the molecule.

As a cured product of the epoxy resin, any known material can be used, as long as the material is a cured product of a monomer or an oligomer having an epoxy group in the molecule.

Examples of the epoxy resin include, but are not limited to, a water-dispersed resin, a solvent-free resin, a solid resin, a heat-curable resin, a curing agent mixed-type resin, and an ultraviolet-curable resin. Among these resins, the heat-curable resin and the ultraviolet-curable resin are preferred, and the ultraviolet-curable resin is more preferred. Note that, even an ultraviolet-curable resin may be heated, and even after ultraviolet curing, it is preferable to perform heating.

Examples of the epoxy resin include, but are not limited to, bisphenol A type resins, bisphenol F type resins, novolak resins, cyclic aliphatic resins, long chain aliphatic resins, glycidyl amine resins, glycidyl ether resins, and glycidyl ester resins. These resins may be used alone or in combination of two or more types.

The epoxy resin is preferably mixed with a curing agent and various types of additives, if desired.

The curing agents are classified into amine-based curing agents, acid anhydride-based curing agents, polyamide-based curing agents, and other types of curing agents. The curing agent is appropriately selected according to a purpose.

Examples of the amine-based curing agents include, but are not limited to, aliphatic polyamines such as diethylenetriamine and triethylenetetramine, and aromatic polyamines such as metaphenylenediamine, diaminodiphenylmethane, and diaminodiphenylsulfone.

Examples of the acid anhydride-based curing agents include, but are not limited to, phthalic anhydride, tetrahydrophthalic anhydride, hexahydrophthalic anhydride, methyltetrahydrophthalic anhydride, methyl nadic anhydride, pyromellitic anhydride, HET acid anhydride, and dodecenylsuccinic anhydride.

Examples of the other curing agents include, but are not limited to, imidazoles and polymercaptans. These curing agents may be used alone or in combination of two or more types.

Examples of the additives include, but are not limited to, a filling material (filler), a gap agent, a polymerization initiator, a drying agent (moisture absorbent), a curing promoter, a coupling agent, a flexibilizing agent, a colorant, a flame retardant auxiliary, an antioxidant, and an organic solvent. Among these additives, the filling material, the gap agent, the curing promoter, the polymerization initiator, and the drying agent (moisture absorbent) are preferred, and the filling material and the polymerization initiator are more preferred.

The filling material is effective in suppressing the intrusion of moisture and oxygen. In addition, by using the filling material, it is possible to obtain effects including reducing the volumetric shrinkage during curing, reducing the amount of outgassing during curing or heating, improving the mechanical strength, and controlling the thermal conductivity and fluidity. Thus, stable output can be efficiently maintained in various environments. In particular, the output characteristics and the durability of photoelectric conversion elements are not only affected by the simple intrusion of moisture and oxygen, but also by the outgassing that occurs when a sealing member is cured or heated, which is an effect that cannot be ignored.

In particular, the outgassing that occurs during heating has a significant effect on the output characteristics when a photoelectric conversion element is stored in a high-temperature environment.

In this case, if the sealing member includes a filling material, a gap agent, and a drying agent, these materials can suppress the intrusion of moisture and oxygen. Further, by reducing the amount of material being used in the sealing member, it is possible to obtain an effect of reducing outgassing. This is effective not only during curing, but also when the photoelectric conversion element is stored in a high-temperature environment.

The filling material is not particularly limited and can be appropriately selected according to a purpose. Preferable examples of the filling material include, but are not limited to, inorganic filling materials such as crystalline or amorphous silica, talc, alumina, aluminum nitride, silicon nitride, calcium silicate, and calcium carbonate. These filling materials may be used alone or in combination of two or more types.

The average primary particle diameter of the filling material is preferably 0.1 μm or more and 10 μm or less, and more preferably 1 μm or more and 5 μm or less. When the amount of the filling material being added is within a preferred range, an effect of suppressing the intrusion of moisture and oxygen can be sufficiently obtained, an appropriate viscosity is obtained, and it is also effective in improving the adhesion to the substrate and the degassing properties, and in controlling the width of the sealing member and the workability.

The content of the filling material is preferably 10 parts by mass or more and 90 parts by mass or less, and more preferably 20 parts by mass or more and 70 parts by mass or less, with respect to 100 parts by mass of the total amount of the sealing member. When the content of the filling material is within the above-mentioned ranges, the effect of suppressing the intrusion of moisture and oxygen is sufficiently obtained, an appropriate viscosity is obtained, and the adhesion and workability are also good.

The gap agent is also referred to as a gap control agent or a spacer agent, and by using the gap agent, it is possible to control a gap of the sealing member. For example, when a sealing member is applied onto the first substrate or the first electrode, and then, a second substrate is placed on the sealing member to perform sealing, the gap of the sealing member can be easily controlled, because the gap agent is mixed into the epoxy resin, so that the gap of the sealing member is aligned to the size of the gap agent.

Any known material can be used as the gap agent, as long as the material is granular, has a uniform particle diameter, and has high solvent resistance and heat resistance. The material of the gap agent preferably has high affinity to the epoxy resin and a spherical particle shape. Specific examples of the material of the gap agent include, but are not limited to, glass beads, fine silica particles, and fine organic resin particles. These materials may be used alone or in combination of two or more types.

The average particle diameter of the gap agent can be selected in accordance with the gap of the sealing member to be set. However, the average particle diameter is preferably 1 μm or more and 100 μm or less, and more preferably 5 μm or more and 50 μm or less.

Examples of the polymerization initiator include, but are not limited to, a thermal polymerization initiator that uses heat to initiate polymerization, and a photopolymerization initiator that uses light to initiate polymerization.

The thermal polymerization initiator is a compound that uses heat to generate active species such as radicals and cations. Specific examples of the thermal polymerization initiator include, but are not limited to, azo compounds such as 2,2′-azobisbutyronitrile (AIBN) and peroxides such as benzoyl peroxide (BPO). Examples of a thermal cationic polymerization initiator include, but are not limited to, benzenesulfonate esters and alkylsulfonium salts.

On the other hand, in the case of an epoxy resin, a cationic photopolymerization initiator is preferably used as the photopolymerization initiator. When an epoxy resin is mixed with a cationic photopolymerization initiator and irradiated with light, the cationic photopolymerization initiator decomposes to generate a strong acid. The acid induces polymerization of the epoxy resin and thus, the curing reaction progresses. The cationic photopolymerization initiator has little volumetric shrinkage during curing, is not inhibited by oxygen, and has high storage stability.

Examples of the cationic photopolymerization initiator include, but are not limited to, aromatic diazonium salts, aromatic iodonium salts, aromatic sulfonium salts, methacerone compounds, and silanol-aluminum complexes.

Further, a photoacid generator having a function of generating an acid by irradiation with light can also be used. The photoacid generator acts as an acid that initiates cationic polymerization. Examples of the photoacid generator include, but are not limited to, onium salts such as ionic sulfonium salts and iodonium salts that include a cationic moiety and an anionic moiety. These materials may be used alone or in combination of two or more types.

The amount of the polymerization initiator to be added may vary depending on the material used. However, the amount of the polymerization initiator is preferably 0.5 parts by mass or more and 10 parts by mass or less, and more preferably 1 part by mass or more and 5 parts by mass or less, with respect to the total amount of 100 parts by mass of the sealing member. When the amount of the polymerization initiator being added is within the above-mentioned ranges, the curing proceeds appropriately, the remaining amount of uncured material can be reduced, and excessive outgassing can be prevented, which is effective.

The drying agent is also referred to as a moisture absorbent, and is a material having a function of physically or chemically adsorbing moisture. If the sealing member includes a drying agent, the moisture resistance may be further increased and the impact of outgassing may be reduced, which is effective.

The drying agent is preferably in particulate form, and examples thereof include, but are not limited to, inorganic water-absorbing materials such as calcium oxide, barium oxide, magnesium oxide, magnesium sulfate, sodium sulfate, calcium chloride, silica gel, molecular sieves, and zeolite. Among these drying agents, zeolite and calcium oxide, which have a large moisture absorption capacity, are preferable. These drying agents may be used alone or in combination of two or more types.

The curing promoter is also referred to as a curing catalyst, is used for the purpose of accelerating the curing speed, and is mainly used for thermosetting epoxy resins.

Examples of the curing promoter include, but are not limited to, tertiary amines or tertiary amine salts such as 1,8-diazabicyclo(5,4,0)-undecene-7 (DBU) and 1,5-diazabicyclo(4,3,0)-nonene-5 (DBN); imidazoles such as 1-cyanoethyl-2-ethyl-4-methylimidazole and 2-ethyl-4-methylimidazole; and phosphines or phosphonium salts such as triphenylphosphine and tetraphenylphosphonium tetraphenylborate. These curing promoters may be used alone or in combination of two or more types.

The coupling agent has an effect of increasing the molecular bonding strength. Examples of the coupling agent include, but are not limited to, silane coupling agents. Examples of the silane coupling agents include, but are not limited to, 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)3-aminopropylmethyldimethoxysilane, N-(2-aminoethyl)3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)3-aminopropyltrimethoxysilane hydrochloride, and 3-methacryloxypropyltrimethoxysilane. These coupling agents may be used alone or in combination of two or more types.

Further, known epoxy resin compositions that are commercially available as sealing materials or adhesives, and can also be effectively used as the sealing member in the present embodiment. Some of these known epoxy resin compositions have been developed and are commercially available for use in solar cells and organic EL devices. Examples of such epoxy resin compositions include, but are not limited to, TB3118, TB3114, TB3124, and TB3125F (all manufactured by ThreeBond Co., Ltd.), WORLD ROCK 5910, WORLD ROCK 5920, and WORLD ROCK 8723 (all manufactured by Kyoritsu Chemical Co., Ltd.), and WB90US(P) (manufactured by Moresco Corporation).

Examples of commercially available acrylic resins include, but are not limited to, products by the trade names of TB3035B and TB3035C (both manufactured by ThreeBond Co., Ltd.) and NICHIBAN UM (manufactured by Nichiban Co., Ltd.).

These sealing members can be cured by irradiation with ultraviolet light or the like and then subjected to a heat treatment, which is effective in the present embodiment. By performing the heat treatment, the amount of uncured components may be reduced, the amount of outgassing that impacts the output characteristics is reduced, and the sealing performance is improved, which is effective in improving the output characteristics and the durability of the output characteristics.

On the other hand, the glass resin having a low melting point is fired after application to decompose the resin components, and then, melted with an infrared laser or the like to cause the product to closely adhere to the glass substrate to perform sealing. At this time, glass components having a low melting point diffuse into the metal oxide layer and are physically bonded, and thus, high sealing performance can be obtained. Further, when the resin components are eliminated, outgassing does not occur as in the case of an ultraviolet curable resin, which is effective in increasing the durability of the photoelectric conversion element. Generally, glass frit or glass paste is commercially available, and these can be effectively used. In one embodiment, a resin having a lower melting point is preferred.

The temperature in the heat treatment is not particularly limited and can be freely set in accordance with the sealing member being used. However, the temperature is preferably 50° C. or higher and 200° C. or lower, more preferably 60° C. or higher and 150° C. or lower, and even more preferably 70° C. or higher and 100° C. or lower. The time of the heat treatment is not particularly limited and can be freely set in accordance with the sealing member being used. However, the time is preferably 10 minutes or longer and 10 hours or shorter, more preferably 20 minutes or longer and 5 hours or shorter, and even more preferably 30 minutes or longer and 3 hours or shorter.

In one embodiment, a sheet-shaped sealing material can also be effectively used.

The sheet-shaped sealing material is obtained by forming in advance an epoxy resin layer or a pressure-sensitive adhesive layer on a sheet. The sheet includes glass, a film having high gas barrier properties, or the like, and the sheet corresponds to the second substrate.

The sheet-shaped sealing material is attached onto the second electrode of the photoelectric conversion element and then cured, so that the sealing member and the substrate can be formed in one process. If the resin layer formed on the sheet is formed over the entire surface of the sheet, the type of sealing is “surface sealing”. However, depending on the formation pattern of the resin layer, the type of sealing may be “frame sealing”, in which a hollow portion is provided inside the photoelectric conversion element.

If the hollow portion inside the sealed interior contains oxygen, it is possible to stably maintain the hole transport function of the hole transport layer during a long period of time, which may be effective in improving the durability of the photoelectric conversion element. Such an effect can be obtained, as long as the oxygen concentration in the hollow portion in the sealed interior formed in the sealing process exceeds 0 vol %. However, the oxygen concentration is preferably 5.0 vol % or more and 21.0 vol % or less, and more preferably 10.0 vol % or more and 21.0 vol % or less.

The oxygen concentration in the hollow portion can be controlled by performing the sealing process in a glove box in which the oxygen concentration is adjusted.

The oxygen concentration can be adjusted by a method of using a gas cylinder having a determined oxygen concentration or by a method of using a nitrogen gas generator.

The oxygen concentration in the glove box can be measured by using a commercially available oxygen concentration meter or an oxygen monitor.

For example, the oxygen concentration in the hollow portion formed by the sealing process can be measured by an in-package moisture and residual gas analysis (IVA) or an atmospheric pressure ionization mass spectrometer (API-MS). Specifically, the photoelectric conversion element is placed in a chamber under high vacuum or filled with an inert gas. The sealing is released inside the chamber, and the gas and the moisture inside the chamber are subjected to mass analysis to quantify all components in the gas contained in the hollow portion. The ratio of oxygen to the sum of all the components is calculated to determine the oxygen concentration.

A gas other than oxygen contained inside the sealed interior is preferably an inert gas, and examples of preferred gases include, but are not limited to, nitrogen and argon.

When the sealing process is performed, it is preferable to control the dew point, together with the oxygen concentration inside the glove box, which is effective in improving the output and the durability of the output. The dew point is defined as the temperature at which condensation starts when a gas containing water vapor is cooled.

The dew point is not particularly limited, but is preferably 0° C. or lower, and more preferably −20° C. or lower. The lower limit of the dew point is preferably −50° C. or higher.

A method of forming the sealing member is not particularly limited and the sealing member can be formed in accordance with a known method. For example, various methods may be used, such as a dispense method, a wire bar method, a spin coating method, a roller coating method, a blade coating method, an inkjet method, a gravure coating method, a letterpress method, an offset method, an intaglio method, a rubber plate method, and a screen printing method.

Further, a passivation layer may be provided between the sealing member and the second electrode. The passivation layer is not particularly limited and can be appropriately selected according to a purpose, as long as the passivation layer is arranged so that the sealing member does not contact the second electrode. However, aluminum oxide, silicon nitride, silicon oxide, and the like are preferably used in the passivation layer.

### <Other Members>

Other members are not particularly limited and can be appropriately selected according to a purpose.

An example of the photoelectric conversion element according to an embodiment of the present invention will be described below with reference to the drawings. However, the present invention is not limited to these examples. For example, the number, the position, the shape, and the like of the constituent members described below that are not described in the present embodiment are also included in the scope of the present invention.

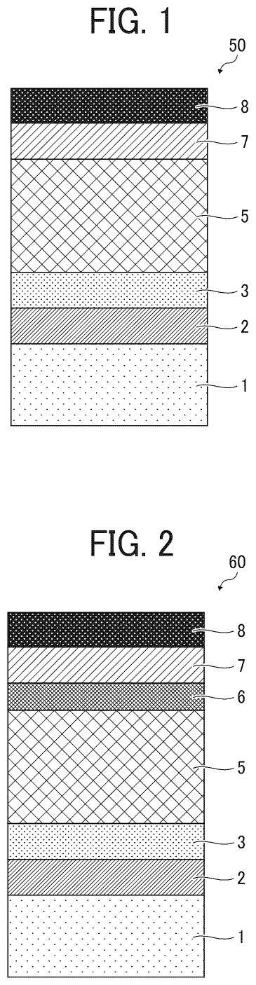

FIG. 1 is a schematic diagram illustrating an inverted structure-type solar cell as a photoelectric conversion element according to an embodiment of the present invention.

A solar cell 50 in FIG. 1 includes a first substrate 1, a first electrode 2, a hole transport layer 3, a perovskite layer 5 serving as a photoelectric conversion layer, a (dense) electron transport layer 7, and a second electrode 8.

The first electrode 2 contacts the hole transport layer 3. The hole transport layer 3 contacts the perovskite layer 5. The perovskite layer 5 contacts the electron transport layer 7. The electron transport layer 7 contacts the second electrode 8.

FIG. 2 is a schematic diagram illustrating another inverted structure-type solar cell as a photoelectric conversion element according to an embodiment of the present invention.

A solar cell 60 in FIG. 2 is an embodiment in which, compared with the solar cell 50 in FIG. 1, a passivation layer 6 is further provided between the perovskite layer 5 and the electron transport layer 7.

### (Photoelectric Conversion Module)

A photoelectric conversion module according to an embodiment of the present invention is a tandem-type photoelectric conversion module and includes a plurality of photoelectric conversion elements layered on each other. In the photoelectric conversion module, adjacent ones of the photoelectric conversion elements are electrically connected in series or parallel. A photoelectric conversion element on the side of a light-receiving surface is a photoelectric conversion element according to an embodiment of the present invention in which the second electrode contains a metal nanowire.

For example, the photoelectric conversion module includes one photoelectric conversion element or a plurality of photoelectric conversion elements on a substrate, and includes the photoelectric conversion element according to an embodiment of the present invention layered on the side of the light-receiving surface. The photoelectric conversion module preferably further includes a second substrate different from the substrate mentioned above, a sealing member, and if desired, includes another member.

An example of the photoelectric conversion module includes, but is not limited to, a solar cell module.

In the tandem-type photoelectric conversion module, a top cell (i.e., a photoelectric conversion element on a side of a light-receiving surface) may be used in which a first electrode containing a metal nanowire and a second electrode (a translucent counter electrode) containing a metal nanowire are combined. Such a top cell has excellent infrared light transmittance, and thus, high conversion efficiency can be achieved in the photoelectric conversion module.

When the number n of photoelectric conversion elements to be layered is 3 or more, the photoelectric conversion elements from the photoelectric conversion element closest to the side of the light-receiving surface to the (n−1)th photoelectric conversion element from the side of the light-receiving surface may be the photoelectric conversion element according to an embodiment of the present invention in which the second electrode contains a metal nanowire. Further, one photoelectric conversion element on the opposite side of the light-receiving surface may be a known photoelectric conversion element or the photoelectric conversion element according to an embodiment of the present invention.

The photoelectric conversion module may be a tandem-type photoelectric conversion module in which the photoelectric conversion elements in each layer of the tandem-type photoelectric conversion module are formed by a plurality of photoelectric conversion elements. Alternatively, the photoelectric conversion module may be a single-layer photoelectric conversion module that is not a tandem-type photoelectric conversion module and includes a plurality of photoelectric conversion elements in the same plane. The photoelectric conversion module may be a photoelectric conversion module in which a plurality of the photoelectric conversion elements are provided on a substrate or in the same layer. In the photoelectric conversion module, it is preferable that, in at least two photoelectric conversion elements adjacent to each other, the hole transport layers are continuous with each other, and the first electrode, the electron transport layer, and the photoelectric conversion layer in the at least two photoelectric conversion elements adjacent to each other are separated by the hole transport layers. In such a photoelectric conversion module, the electron transport layer and the photoelectric conversion layer are disconnected, so that the recombination of electrons due to diffusion is reduced, and thus, it possible to maintain power generation efficiency, even after the photoelectric conversion module is exposed to high-intensity light during a long period of time.

When the photoelectric conversion module is combined with a circuit board and the like that controls the generated current, the photoelectric conversion module can be applied to a power supply device. Examples of appliances that utilize power supply devices include, but are not limited to, electronic desk calculators and wristwatches. Moreover, the power supply device including the photoelectric conversion module can be applied to mobile phones, electronic notebooks, electronic paper, and the like. Further, a power supply device including the photoelectric conversion module according to an embodiment of the present invention can be used as an auxiliary power source to extend the continuous usage time of rechargeable or battery-powered electrical appliances, or as a power source that can be utilized at night and the like by combining the power source with a secondary battery and the like. Further, the power supply device can be used as an independent power source that does not require battery replacement, power wiring, or the like in IoT devices and artificial satellites.

### (Solar Cell Module)

The solar cell module according to an embodiment of the present invention is a tandem-type solar cell module and includes a plurality of photoelectric conversion elements layered on each other. In the solar cell module, adjacent ones of the photoelectric conversion elements are electrically connected in series or parallel. A photoelectric conversion element on the side of a light-receiving surface is a photoelectric conversion element according to an embodiment of the present invention in which the second electrode contains a metal nanowire.

The solar cell module is similar to the photoelectric conversion module.

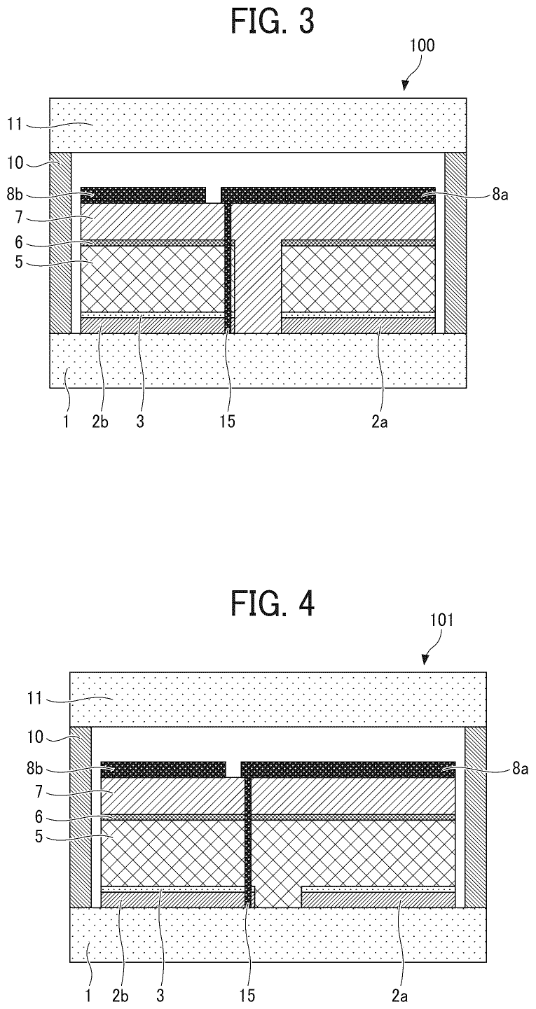

FIG. 3 is a cross-sectional view of a solar cell module according to an embodiment of the present invention. As illustrated in FIG. 3, a solar cell module 100 includes, on the first substrate 1, photoelectric conversion elements a and b including respective first electrodes 2a and 2b (may be collectively referred to as the first electrode 2), the hole transport layer 3, the perovskite layer 5, the passivation layer 6, the electron transport layer 7, and respective second electrodes 8a and 8b (may be collectively referred to as the second electrode 8). The first electrode 2 and the second electrode 8 have a conductive path leading to an output terminal.

Further, in the solar cell module 100, a second substrate 11 is arranged facing the first substrate 1, to sandwich the photoelectric conversion elements a and b therebetween, and a sealing member 10 is arranged between the first substrate 1 and the second substrate 11.

In the solar cell module 100, the first electrodes 2a and 2b, the hole transport layer 3, the perovskite layer 5, and the passivation layer 6 in the photoelectric conversion element a and in the photoelectric conversion element b are separated from each other by the electron transport layer 7 forming a continuous layer that extends between the photoelectric conversion element a and the photoelectric conversion element b.

FIG. 4 is a cross-sectional view of a solar cell module according to an embodiment of the present invention. As illustrated in FIG. 4, a solar cell module 101 includes, on the first substrate 1, photoelectric conversion elements a and b including respective first electrodes 2a and 2b, the hole transport layer 3, the perovskite layer 5, the passivation layer 6, the electron transport layer 7, and respective second electrodes 8a and 8b. The first electrode 2 and the second electrode 8 have a conductive path leading to an output terminal.

Further, in the solar cell module 101, the second substrate 11 is arranged facing the first substrate 1, to sandwich the photoelectric conversion elements a and b therebetween, and the sealing member 10 is arranged between the first substrate 1 and the second substrate 11.

In the solar cell module 101, the first electrodes 2a and 2b and the hole transport layer 3 in the photoelectric conversion element a and in the photoelectric conversion element b are separated from each other by the perovskite layer 5, the passivation layer 6, and the electron transport layer 7, which form continuous layers extending between the photoelectric conversion element a and the photoelectric conversion element b.

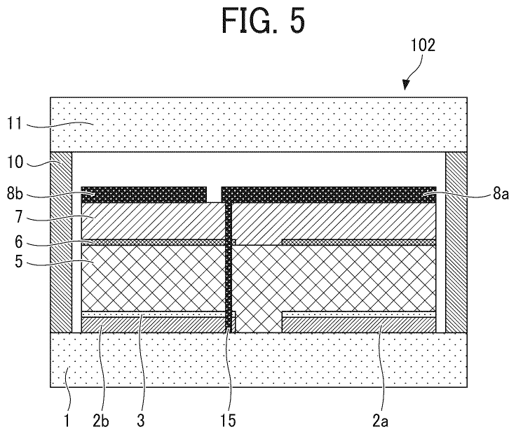

FIG. 5 is a cross-sectional view of a solar cell module of according to an embodiment of the present invention. As illustrated in FIG. 5, a solar cell module 102 includes, on the first substrate 1, photoelectric conversion elements a and b including respective first electrodes 2a and 2b, the hole transport layer 3, the perovskite layer 5, the passivation layer 6, the electron transport layer 7, and respective second electrodes 8a and 8b. The first electrode 2 and the second electrode 8 have a conductive path leading to an output terminal.

Further, in the solar cell module 102, the second substrate 11 is arranged facing the first substrate 1, to sandwich the photoelectric conversion elements a and b therebetween, and the sealing member 10 is arranged between the first substrate 1 and the second substrate 11.

In the solar cell module 102, the first electrodes 2a and 2b, the hole transport layer 3, and the passivation layer 6 in the photoelectric conversion element a and in the photoelectric conversion element b are separated from each other by the perovskite layer 5 and the electron transport layer 7, which form continuous layers extending between the photoelectric conversion element a and the photoelectric conversion element b.

The solar cell modules 100 to 102 are sealed by the first substrate 1, the sealing member 10, and the second substrate 11. Therefore, it is possible to control the moisture content and the oxygen concentration in the hollow portion present between the second electrode 8 and the second substrate 11. By controlling the moisture content and the oxygen concentration in the hollow portions of the solar cell modules 100 to 102, the power generation performance and the durability can be improved. That is, if the solar cell module further includes a second substrate arranged facing the first substrate to sandwich the photoelectric conversion element therebetween, and a sealing member arranged between the first substrate and the second substrate to seal the photoelectric conversion element, the moisture content and the oxygen concentration in the hollow portion can be controlled, and thus, it is possible to improve the power generation performance and the durability.

The oxygen concentration in the hollow portion is not particularly limited and can be appropriately selected according to a purpose. However, the oxygen concentration is preferably 0% or more and 21% or less, more preferably 0.05% or more and 10% or less, and even more preferably 0.1% or more and 5% or less.

Further, in the solar cell modules 100 to 102, the second electrode 8 and the second substrate 11 do not contact each other, so that peeling or damage of the second electrode 8 can be prevented.

Further, the solar cell modules 100 to 102 include a through portion 15 that electrically connects the photoelectric conversion element a and the photoelectric conversion element b. In the solar cell modules 100 to 102, the second electrode 8a of the photoelectric conversion element a and the first electrode 2b of the photoelectric conversion element b are electrically connected by the through portion 15 penetrating the electron transport layer 7, so that the photoelectric conversion element a and the photoelectric conversion element b are connected in series. Thus, by connecting a plurality of photoelectric conversion elements in series, the open circuit voltage of the solar cell module can be increased.

Note that the through portion 15 may penetrate the first electrode 2 and extend to the first substrate 1, or the processing for providing the through portion 15 may be stopped inside the first electrode 2 and the through portion 15 may not extend to the first substrate 1.

When the through portion 15 has the shape of micropores that penetrate the first electrode 2 and extend to the first substrate 1, if the total opening area of the micropores is too large compared to the area of the through portion 15, the film cross-sectional area of the first electrode 2 decreases. Therefore, the resistance value increases, which may cause a decrease in the photoelectric conversion efficiency. Thus, the ratio of the total opening area of the micropores to the area of the through portion 15 is preferably 5/100 or more and 60/100 or less.

A method of forming the through portion is not particularly limited and can be appropriately selected according to a purpose. Examples of the method include a sand blasting method, a water blasting method, a chemical etching method, a laser processing method, and a method using abrasive paper. Among these methods, the laser processing method is preferred, because fine holes can be formed without using sand, etching, a resist, and the like, and thus, the material can be processed cleanly with good reproducibility. Further, the laser processing method is also preferable because, when forming the through portion 15, at least one of the hole transport layer 3, the perovskite layer 5, the passivation layer 6, the electron transport layer 7, and the second electrode 8 can be removed by impact peeling using the laser processing method. Thus, it is not necessary to provide a mask during lamination. Further, it is possible to easily remove the material forming the photoelectric conversion element and form the through portion in one process.

Here, the perovskite layer in the photoelectric conversion element a and the perovskite layer in the photoelectric conversion element b may extended one after the other or may be separated. When the perovskite layers are separated, the distance between the perovskite layers is preferably 1 μm or more and 100 μm or less, and more preferably 5 μm or more and 50 μm or less. When the distance between the perovskite layer in the photoelectric conversion element a and the perovskite layer in the photoelectric conversion element b is 1 μm or more and 100 μm or less, a porous titanium oxide layer and the perovskite layer are discontinuous and the recombination of electrons due to diffusion is reduced. Thus, it is possible to maintain power generation efficiency even after exposure to high-intensity light during a long period of time. That is, in at least two photoelectric conversion elements that are adjacent to each other, the distance between the electron transport layer and the perovskite layer in one photoelectric conversion element and the electron transport layer and the perovskite layer in the other photoelectric conversion element is 1 μm or more and 100 μm or less. Therefore, it is possible to maintain the power generation efficiency even after exposure to high-intensity light during a long period of time.

In at least two photoelectric conversion elements that are adjacent to each other, the distance between the electron transport layer and the perovskite layer in one photoelectric conversion element and the electron transport layer and the perovskite layer in the other photoelectric conversion element refers to the distance of the shortest portion between outer peripheral portions (end portions) of the electron transport layers and the perovskite layers in the photoelectric conversion elements.

If the solar cell module of the present embodiment is combined with a circuit board and the like that controls the generated current, the solar cell module can be applied to a power supply device. Examples of appliances that utilize power supply devices include, but are not limited to, electronic desk calculators and wristwatches. Moreover, the power supply device including the photoelectric conversion element of the present embodiment can be applied to mobile phones, electronic notebooks, electronic paper, and the like. Further, a power supply device including the photoelectric conversion element of the present embodiment can be used as an auxiliary power source to extend the continuous usage time of rechargeable or battery-powered electrical appliances, or as a power source that can be utilized at night and the like by combining the power source with a secondary battery and the like. Further, the power supply device can be used as an independent power source that does not require battery replacement, power wiring, or the like in IoT devices and artificial satellites.

### (Electronic Device)

An electronic device according to an embodiment of the present invention includes at least any one of the photoelectric conversion element and the photoelectric conversion module according to embodiments of the present invention, and a device that operates by using electric power generated by photoelectric conversion by at least any one of the photoelectric conversion element and the photoelectric conversion module. If desired, the electronic device according to an embodiment of the present invention further includes another device.

Further, the electronic device according to an embodiment of the present invention includes at least any one of the photoelectric conversion element and the photoelectric conversion module according to embodiments of the present invention, a storage battery that can store electric power generated by photoelectric conversion by at least any one of the photoelectric conversion element and the photoelectric conversion module, and a device that operates by using the electric power stored in the storage battery. If desired, the electronic device according to an embodiment of the present invention further includes another device.

### (Power Supply Module)

A power supply module according to an embodiment of the present invention includes at least any one of the photoelectric conversion element and the photoelectric conversion module according to embodiments of the present invention, a power supply integrated circuit (power supply IC, integrated circuit), and if desired, further includes another device.

### (Solar Water Heater)

A solar water heater according to an embodiment of the present invention includes a heat collector that receives sunlight to collect heat, a hot water storage tank that stores hot water heated by the heat collector, and on a side of a light-receiving surface of the heat collector, the photoelectric conversion element according to an embodiment of the present invention in which the second electrode contains a metal nanowire. If desired, the solar water heater according to an embodiment of the present invention further includes other components such as a liquid delivery pipe, an exterior casing, and a storage battery.

The main body of the solar water heater including the heat collector and the hot water storage tank is not particularly limited, and a known solar water heater can be appropriately selected according to a purpose.

The components such as a liquid delivery pipe that delivers water to the heat collector, a liquid delivery pipe that delivers heated water from the heat collector to the hot water storage tank, a liquid delivery pipe that delivers hot water from the hot water storage tank to an external device, and the exterior casing in which these components are arranged and fixed, are not particularly limited and can be appropriately selected from known components of solar water heaters according to a purpose.

The solar water heater according to an embodiment of the present invention includes, on the side of the light-receiving surface of the heat collector, the photoelectric conversion element according to an embodiment of the present invention, in which the second electrode contains a metal nanowire. The photoelectric conversion element converts light energy into electric energy, and the photoelectric conversion element has high infrared light transmittance, so that infrared light permeating into the photoelectric conversion element is collected and can be efficiently utilized to heat hot water. In addition, the heat generated by the operation of the photoelectric conversion element can be utilized to heat the hot water. This contributes to increasing the efficiency of the solar water heater.

Further, the solar water heater includes a storage battery that can store the electric power generated by the photoelectric conversion in the photoelectric conversion element, and thus, the generated electric power can be used to drive the solar water heater main body at a desired timing.

### EXAMPLES

The present invention will be described below with reference to Examples and Comparative Examples. Note that the present invention is not limited to the Examples described herein.

### Synthesis Examples

### <<Synthesis of Styrene Derivatives>>

4-Chloromethylstrylene (manufactured by Tokyo Chemical Industry Co., Ltd., 25 g) and triphenylphosphine (manufactured by Tokyo Chemical Industry Co., Ltd., 45.1 g) were placed in a 300 ml four-neck flask. 50 ml of toluene was added to the flask and the mixture was stirred under reflux during 2 hours. After the mixture was cooled, ethyl acetate was added and the mixture was filtered. 45.1 g of a white solid powder of a styrene derivative having the structure below was obtained.

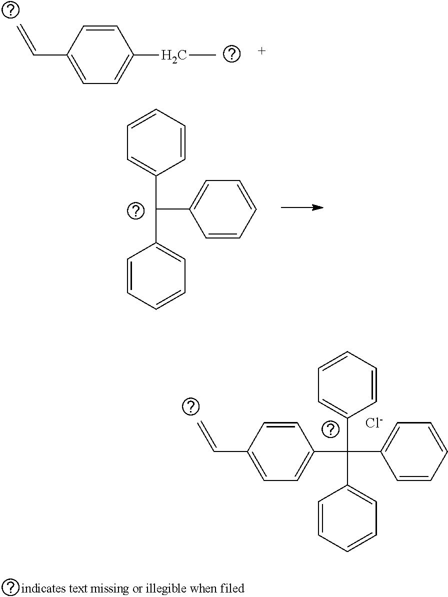

### <<Synthesis of Pyridine Derivative 1>>

4,4′-((4-Bromophenyl)azanediyl)dibenzaldehyde (manufactured by BLD-Pharm, 1.14 g), 4-pyridylbononic acid (manufactured by Tokyo Chemical Industry Co., Ltd., 0.55 g), and potassium carbonate (manufactured by Kanto Chemical Co., Inc., 0.42 g) were dissolved in tetrahydrofuran/methanol (30 ml/30 ml), and the mixture was stirred at room temperature in the presence of argon. Tetrakis (triphenylphosphine) palladium (0) (manufactured by Tokyo Chemical Industry Co., Ltd., 0.173 g) was added, and the mixture was stirred under reflux during 4 hours. The obtained product was extracted with dichloromethane, filtered, and washed.

The obtained product was purified in a column using ethyl acetate/dichloromethane (3/2 vol) to obtain 1.15 g of a clear liquid of Pyridine Derivative 1 having the structure below.

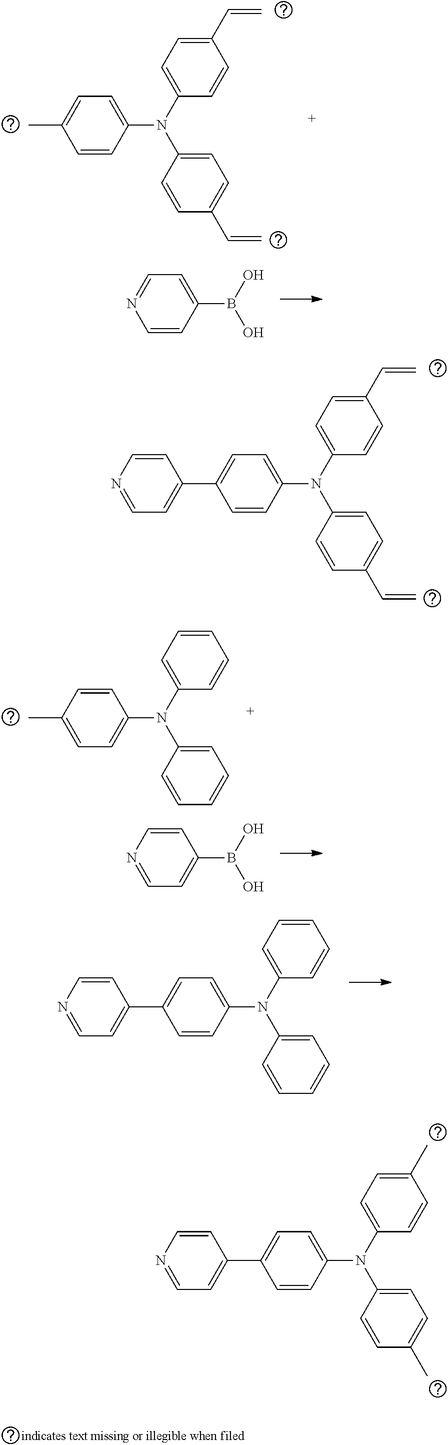

### Synthesis Example 1. Synthesis Example of Compound No. 1

Pyridine Derivative 1 (1.15 g) and a styrene derivative (2.74 g) were dissolved in 100 ml of dehydrated dimethylformamide. Potassium tert-butoxide (manufactured by Kanto Chemical Co., Inc., 0.8 g) was added in the presence of argon gas at 3 to 5 degrees, and then, the mixture was stirred at room temperature during 2 hours. The mixture was neutralized by using acetic acid and the obtained product was extracted with dichloromethane. The obtained product was concentrated under reduced pressure, and then, purified in a column using dichloromethane/ethyl acetate (1/1 vol). 0.85 g of Compound No. 1 having the structure below was obtained.

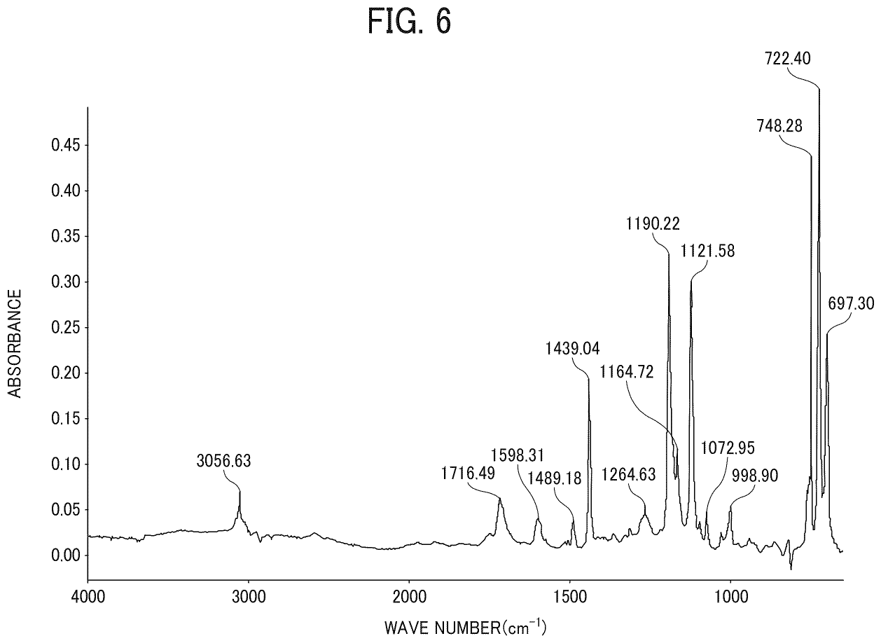

The FT-IR of the obtained Compound No. 1 was measured by using a Fourier transform infrared spectrometer (FT-IR, device name: IR TRACER-100, manufactured by Shimadzu Corporation), and the IR spectrum illustrated in FIG. 6 was obtained. Thus, it was possible to identify Compound No. 1 and confirm that the desired compound was obtained.

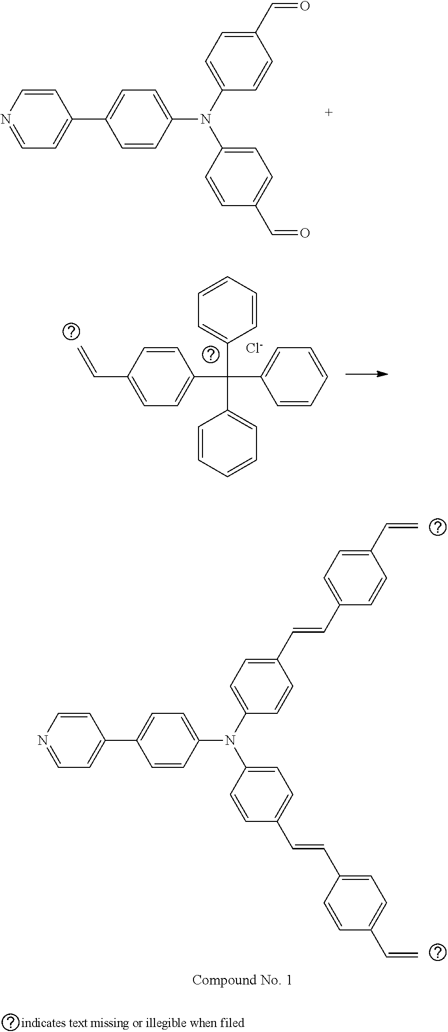

### Example 1

### <Fabrication of Inverted Structure-Type Solar Cell>

A film (15 Ω/sq, transmittance of 80%) of silver nanowires (TranDuctive™ N15, manufactured by GenesInk) was formed by a die coating method on a glass substrate serving as a first substrate, to prepare a first electrode on the first substrate.

Next, a chlorobenzene solution (10 mg/ml) of Compound No. 1 serving as a hole transport material was applied onto the first electrode by using a spin coating method, and then, dried by heating at 200° C. for 20 minutes. The hole transport layer was applied so that the average thickness of the hole transport layer was 10 nm to 40 nm.

Next, lead(II) iodide (0.5306 g), lead(II) bromide (0.0736 g), methylamine bromide (0.0224 g), and formamidine iodide (0.1876 g) were added to N,N-dimethylformamide (0.8 ml) and dimethylsulfoxide (0.2 ml), and the mixture was stirred and heated at 60° C. The obtained solution was applied onto the hole transport layer by using a spin coating method, while adding chlorobenzene (0.3 ml) to form a perovskite film.

Subsequently, the perovskite film was dried at 150° C. during 30 minutes to form a perovskite layer. The conditions were chosen so that the average thickness of the perovskite layer was 200 nm to 350 nm.

Next, a chlorobenzene solution (10 mg/ml) of phenyl-C61-butyric acid methyl ester (PCBM, manufactured by Frontier Carbon Corporation, E100) was applied by using a spin coating method to form a film having an average thickness of 30 nm. The film was dried by heating at 120° C. during 3 minutes to form an electron transport layer.

Finally, a film (15 Ω/sq, transmittance of 80%) of silver nanowires (TranDuctive™ N15, manufactured by GenesInk) was formed by a die coating method, to prepare a second electrode. Thus, the inverted structure-type solar cell illustrated in FIG. 1 was obtained.

### <Evaluation of Infrared Light Transmittance>

The transmittance at a wavelength of 400 nm to 1600 nm of the first electrode including the first substrate and the metal nanowire prepared in Example 1 was measured by using a spectrophotometer (device name: UV-1280, manufactured by Shimadzu Corporation).

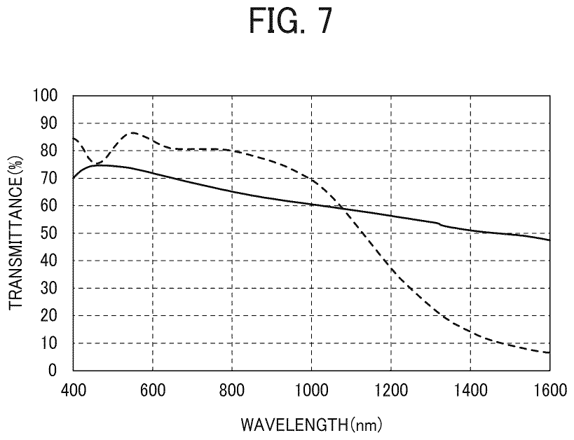

For comparison, an ITO glass substrate (manufactured by Geomatec Co., Ltd.) having a resistance value of 10 Ω/sq was used to measure the transmittance in a similar manner. The results are illustrated in FIG. 7.

In FIG. 7, the horizontal axis represents the wavelength, the vertical axis represents the transmittance (%), the solid line represents the first electrode and the first substrate in Example 1, and the dashed line represents the ITO glass substrate used for comparison.

The results in FIG. 6 indicate that the transmittance of the first electrode and the first substrate in Example 1 is superior to that of the ITO glass substrate used for comparison in the infrared region (in particular, for infrared light from a wavelength of 800 nm, which is not absorbed by perovskite solar cells, to a wavelength of 1400 nm, which is absorbed by CIS solar cells).

### <Evaluation of Light Resistance>

### <<Conversion Efficiency (Evaluation of Solar Cell Characteristics)>>

The light resistance of the obtained solar cell was evaluated from the maintenance factor of the conversion efficiency after a light resistance test.

First, the obtained solar cell was irradiated with light under conditions including AM 1.5G and 100 mW/cm² by using a solar simulator (SS-80XIL, manufactured by EKO INSTRUMENTS CO., LTD.), and the current-voltage characteristics were measured by using a solar cell evaluation system (product name: As-510-PV03, manufactured by NF Corporation). A conversion efficiency η (%) in the solar cell characteristics (initial characteristics) was calculated from the obtained current-voltage curve.

<<Light Resistance (Maintenance Factor of Conversion Efficiency after Light Resistance Test)>>

The initial photoelectric conversion element was subjected to a light resistance test including 500 hours of continuous irradiation (AM 1.5, 100 mW/cm²). The maintenance factor of the conversion efficiency was calculated as a maintenance factor ηx (%) of the conversion efficiency after the light resistance test by the following formula: ηx/η (%), to evaluate the photoelectric conversion element based on the evaluation criteria mentioned below. The results are illustrated in Table 1.

### —Evaluation Criteria—

B: The maintenance factor of the conversion efficiency after the light resistance test is 80% or more, and the light resistance is excellent
C: The maintenance factor of the conversion efficiency after the light resistance test is 60% or more and less than 80%, which is within a range usable in practice
F: The maintenance factor of the conversion efficiency after the light resistance test is less than 60%, which is not within the range usable in practice

### <Evaluation of Heat Resistance>

<<Heat Resistance (Maintenance Factor of Conversion Efficiency after Heat Resistance Test)>>

The initial photoelectric conversion element was subjected to a durability test by storing the initial photoelectric conversion element at 90° C. during 500 hours. The maintenance factor of the conversion efficiency was calculated as a maintenance factor ηx (%) of the conversion efficiency after the durability test by the following formula: ηx/η (%), to evaluate the photoelectric conversion element based on the evaluation criteria mentioned below. The results are illustrated in Table 1.

### —Evaluation Criteria—

B: The maintenance factor of the conversion efficiency after the heat resistance test is 80% or more, and the heat resistance is excellent
C: The maintenance factor of the conversion efficiency after the heat resistance test is 60% or more and less than 80%, which is within a range usable in practice
F: The maintenance factor of the conversion efficiency after the heat resistance test is less than 60%, which is not within the range usable in practice

### Examples 2 to 9

Inverted structure-type solar cells of Examples 2 to 9 were manufactured and evaluated similarly to Example 1, except that the hole transport material in Example 1 was changed to the hole transport materials illustrated in Table 1. The results are illustrated in Table 1.

### Example 10

An inverted structure-type solar cell of Example 10 illustrated in FIG. 2 was manufactured and evaluated similarly to Example 1, except that a 1 mM solution obtained by dissolving 5-aminopentanoic acid hydroiodide as a compound represented by General Formula (8) above in isopropyl alcohol, was applied by using a spin coating method onto the perovskite layer in Example 1 to form a passivation layer containing the compound represented by General Formula (8) above. The results are illustrated in Table 1.

### Example 11

An inverted structure-type solar cell of Example 11 was manufactured and evaluated similarly to Example 1, except that conductive polymers PEDOT/PSS (CLEVIOS™ HTL SOLAR 3, manufactured by Heraeus Group) were added to the silver nanowires (TranDuctive™ N15, manufactured by GenesInk) in Example 1 to obtain a mass ratio of AgNW:PEDOT/PSS of 4:1. The results are illustrated in Table 1.

### Example 12

An inverted structure-type solar cell of Example 12 was manufactured and evaluated similarly to Example 1, except that the material of the perovskite layer in Example 1 was changed to a material obtained by adding lead(II) iodide (2.5471 g), lead(II) bromide (0.3578 g), methylamine bromide (0.1092 g), and formamidine iodide (0.9501 g) to N,N-dimethylformamide (4 ml) and dimethyl sulfoxide (1 ml). The results are illustrated in Table 1.

### Example 13

An inverted structure-type solar cell of Example 13 was manufactured and evaluated similarly to Example 1, except that the material of the perovskite layer in Example 1 was changed to a material obtained by adding lead(II) iodide (2.1437 g), lead(II) bromide (0.4955 g), formamidine iodide (0.1548 g), and cesium iodide (1.325 g) to N,N-dimethylformamide (4 ml) and dimethyl sulfoxide (1 ml). The results are illustrated in Table 1.

### Comparative Example 1

An inverted structure-type solar cell of Comparative Example 1 was manufactured and evaluated similarly to Example 1, except that the hole transport material in Example 1 was changed to [2-(3,6-dibromo-9H-carbazol-9-yl)ethyl]phosphonic acid (Br-2PACz, manufactured by Tokyo Chemical Industry Co., Ltd.) having the structure below. The results are illustrated in Table 1.

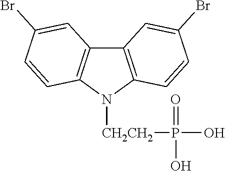

### Comparative Example 2

An inverted structure-type solar cell of Comparative Example 2 was manufactured and evaluated similarly to Example 1, except that the hole transport material in Example 1 was changed to poly[bis(4-phenyl)(2,4,6-trimethylphenyl)amine]represented by the following general formula (PTAA, manufactured by Sigma-Aldrich Corporation, in which n is an integer in the general formula below). The results are illustrated in Table 1.

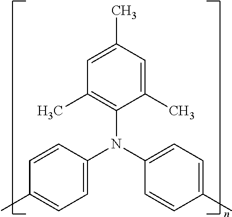

### Comparative Example 3

An inverted structure-type solar cell of Comparative Example 3 was manufactured and evaluated similarly to Example 1, except that the hole transport material in Example 1 was changed to poly(3,4-ethylenedioxythiophene) doped with poly(4-styrenesulfonic acid) (PEDOT/PSS represented by the following general formula, manufactured by Sigma-Aldrich, in which n, x, and y each independently represent an integer). The results are illustrated in Table 1.

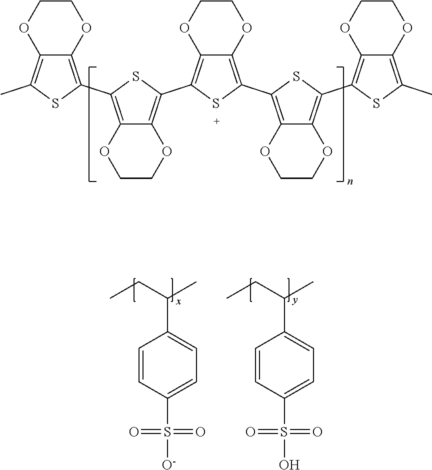

### Comparative Example 4

An inverted structure-type solar cell of Comparative Example 4 was manufactured and evaluated similarly to Example 1, except that the hole transport material in Example 1 was changed to Compound A having the structure below.

The results are illustrated in Table 1.

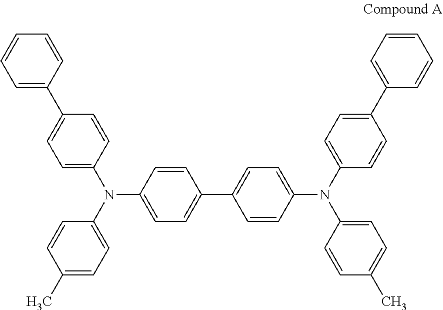 [SMILES: Cc1ccc(N(c2ccc(-c3ccccc3)cc2)c2ccc(-c3ccc(N(c4ccc(C)cc4)c4ccc(-c5ccccc5)cc4)cc3)cc2)cc1]

TABLE 1

| | Hole transport | Light | Heat |
|---|---|---|---|
| | material | resistance | resistance |
| Example 1 | Compound No. 1 | A | B |
| Example 2 | Compound No. 2 | A | B |
| Example 3 | Compound No. 5 | A | B |
| Example 4 | Compound No. 12 | A | B |
| Example 5 | Compound No. 13 | A | B |
| Example 6 | Compound No. 14 | A | B |
| Example 7 | Compound No. 15 | B | B |
| Example 8 | Compound No. 18 | B | C |
| Example 9 | Compound No. 20 | A | B |
| Example 10 | Compound No. 1 | B | A |
| Example 11 | Compound No. 1 | A | B |
| Example 12 | Compound No. 1 | A | C |
| Example 13 | Compound No. 1 | A | A |
| Comparative | Br-2PACz | F | F |
| Example 1 | | | |
| Comparative | PTAA | C | F |
| Example 2 | | | |
| Comparative | PEDOT/PSS | F | C |
| Example 3 | | | |
| Comparative | Compound A | F | F |
| Example 4 | | | |

The results in Table 1 indicate that in Examples 1 to 13, when the hole transport material includes a polymerizable group and the hole transport layer contains a polymer of the hole transport material, the filling properties and the coverage properties in-between the silver nanowires are good. Therefore, it is possible to protect the material of the perovskite layer from the diffusion of halogen ions and obtain light resistance and heat resistance. In particular, in Examples 1 to 6, it was found that, when the hole transport material includes a pyridine group, it can be assumed that a passivation effect is obtained by the coordination of an unpaired electron to the lead atom in the perovskite layer, and thus, high light resistance can be obtained.

### Example 14: Manufacturing of Solar Cell Module

The solar cell of Example 1 was layered on and electrically connected in series to an upper portion (on the side of the light-receiving surface) of a monocrystalline silicon solar cell (KXOB25-04X3F, manufactured by Anysolar, Ltd.) to manufacture a tandem-type solar cell module of Example 14.

The obtained solar cell module was used to evaluate the output at AM 1.5 and 100 mW/cm². The obtained output was 30.8 mW.

### Comparative Example 5

A monocrystalline silicon solar cell was used as a solar cell module of Comparative Example 5, in which the solar cell of Example 1 was not layered on the upper portion (on the side of the light-receiving surface) of the monocrystalline silicon solar cell (KXOB25-04X3F, manufactured by Anysolar, Ltd.). The output was evaluated similarly to Example 14. The obtained output was 22.0 mW.

### Comparative Example 6

A tandem-type solar cell module of Comparative Example 6 was manufactured similarly to Example 14, except that in the solar cell of Example 1 used in the solar cell module of Example 14, the first substrate and the first electrode were changed to an ITO glass substrate (manufactured by Geomatec Co., Ltd.) having a resistance value of 10 Ω/sq. The output was evaluated similarly to Example 14. The obtained output was 27.5 mW.

The results of Example 14 and Comparative Examples 5 and 6 indicate that, compared with a perovskite solar cell module (Comparative Example 6) using a single-layer monocrystalline silicon solar cell (Comparative Example 5) and an ITO glass substrate, by using the perovskite solar cell module using silver nanowires having high infrared light transmittance (Example 14), it is possible to obtain higher output when the module is evaluated as a tandem-type solar cell module.

Aspects of the present invention include the following, for example.

According to a first aspect, a photoelectric conversion element includes a first electrode including a metal nanowire, a hole transport layer over the first electrode and including a polymer of a hole transport material, a photoelectric conversion layer over the hole transport layer, an electron transport layer over the photoelectric conversion layer, and a second electrode over the electron transport layer.

According to a second aspect, in the photoelectric conversion element according to the first aspect, the hole transport material includes a pyridine group.

According to a third aspect, the photoelectric conversion element according to the second aspect is represented by General Formula (1) below:

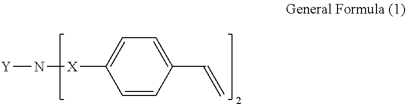

where X represents an aromatic hydrocarbon group or an aromatic hydrocarbon group including a substituent, and Y represents a pyridine group or a pyridine group including a substituent.

According to a fourth aspect, in the photoelectric conversion element according to the third aspect, X in General Formula (1) is represented by one of the groups below:

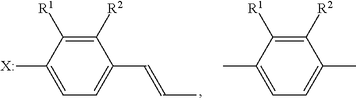

where R¹ and R² each independently represent a hydrogen atom or a methyl group, and
Y in General Formula (1) is represented by one of the groups below:

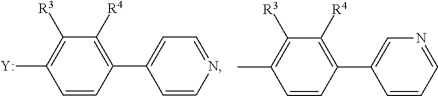

where R₃ and R₄ each independently represent a hydrogen atom or a methyl group.

According to a fifth aspect, in the photoelectric conversion element according to any one of the first aspect to the fourth aspect, the metal nanowire includes a silver nanowire.

According to a sixth aspect, in the photoelectric conversion element according to any one of the first aspect to the fifth aspect, the photoelectric conversion layer includes a perovskite compound represented by General Formula (5) below:

X_{α}Y_{β}Z_{γ} General Formula (5)
where a ratio of α:β:γ is 3:1:1, β and γ each represent an integer greater than 1, X represents a halogen atom, Y represents an organic compound having an amino group, and Z represents a metal ion.

According to a seventh aspect, in the photoelectric conversion element according to any one of the first aspect to the sixth aspect, the photoelectric conversion layer includes at least one of methylamine, ethylamine, n-butylamine, or formamidine.

According to an eighth aspect, the photoelectric conversion element according to any one of the first aspect to the seventh aspect further includes a passivation layer between the photoelectric conversion layer and the electron transport layer, and the passivation layer includes an amine compound different from a compound included in the photoelectric conversion layer.

According to a ninth aspect, in the photoelectric conversion element according to any one of the first aspect to the eighth aspect, the second electrode includes a metal nanowire.

According to a tenth aspect, in the photoelectric conversion element according to any one of the first aspect to the ninth aspect, the first electrode further includes a conductive polymer, and
a mass ratio (A/B) of the metal nanowire (A) to the conductive polymer (B) in the first electrode is 2 or more and 6 or less.

According to an eleventh aspect, a solar cell module includes photoelectric conversion elements laminated in a plurality of layers, including the photoelectric conversion element according to the ninth aspect on a side of a light-receiving surface of the solar cell module, and
adjacent ones of the photoelectric conversion elements are electrically connected in series or in parallel.

According to a twelfth aspect, a solar water heater includes a heat collector that receives sunlight and collects heat,
a hot water storage tank to store hot water heated by the heat collector, and
the photoelectric conversion element according to the ninth aspect or the tenth aspect, or the solar cell module according to the eleventh aspect on a side of a light receiving surface of the heat collector.

According to the photoelectric conversion element according to any one of the first aspect to the tenth aspect, the solar cell module according to the eleventh aspect, and the solar water heater according to the twelfth aspect, it is possible to solve the above-described problems in the related art and achieve the object of the present embodiment.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A photoelectric conversion element comprising:
a first electrode including a metal nanowire;
a hole transport layer over the first electrode, the hole transport layer including a polymer of a hole transport material;
a photoelectric conversion layer over the hole transport layer;
an electron transport layer over the photoelectric conversion layer; and
a second electrode over the electron transport layer.

2. The photoelectric conversion element according to claim 1, wherein the hole transport material includes a pyridine group.

3. The photoelectric conversion element according to claim 2, wherein the hole transport material is represented by General Formula (1) below: 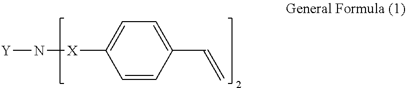
where X represents an aromatic hydrocarbon group or an aromatic hydrocarbon group including a substituent, and Y represents a pyridine group or a pyridine group including a substituent.

4. The photoelectric conversion element according to claim 3, wherein
X in General Formula (1) is represented by one of the groups below: 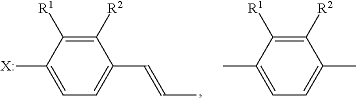
where R¹ and R² each independently represent a hydrogen atom or a methyl group, and
Y in General Formula (1) is represented by one of the groups below: 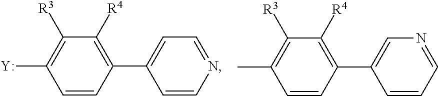
where R³ and R⁴ each independently represent a hydrogen atom or a methyl group.

5. The photoelectric conversion element according to claim 1, wherein the metal nanowire includes a silver nanowire.

6. The photoelectric conversion element according to claim 1, wherein the photoelectric conversion layer includes a perovskite compound represented by General Formula (5) below:
X_{α}Y_{β}Z_{γ} General Formula (5)
where a ratio of α:β:γ is 3:1:1, β and γ each represent an integer greater than 1, X represents a halogen atom, Y represents an organic compound having an amino group, and Z represents a metal ion.

7. The photoelectric conversion element according to claim 1, wherein the photoelectric conversion layer includes at least one of methylamine, ethylamine, n-butylamine, or formamidine.

8. The photoelectric conversion element according to claim 1, further comprising a passivation layer between the photoelectric conversion layer and the electron transport layer,
the passivation layer including an amine compound different from a compound included in the photoelectric conversion layer.

9. The photoelectric conversion element according to claim 1, wherein the second electrode includes a metal nanowire.

10. The photoelectric conversion element according to claim 1, wherein
the first electrode further includes a conductive polymer, and
a mass ratio of the metal nanowire to the conductive polymer in the first electrode is 2 or more and 6 or less.

11. A solar cell module comprising:
photoelectric conversion elements laminated in a plurality of layers, including the photoelectric conversion element according to claim 9 on a side of a light-receiving surface of the solar cell module,
adjacent ones of the photoelectric conversion elements being electrically connected in series or in parallel.

12. A solar water heater comprising:
a heat collector to receive sunlight and collect heat;
a hot water storage tank to store hot water heated by the heat collector; and
the photoelectric conversion element according to claim 9 on a side of a light receiving surface of the heat collector.
